(19) United States
(12) Patent Application Publication
(10) Pub. No.: US 2025/0101297 A1
(43) Pub. Date: Mar. 27, 2025

(54) QUANTUM DOT, LIGHT EMITTING ELEMENT, AND DISPLAY DEVICE

(71) Applicant: Samsung Display Co., Ltd., Yongin-si (KR)

(72) Inventors: SUNGJAE KIM, Yongin-si (KR); Youngsik KIM, Yongin-si (KR); Bitna YOON, Yongin-si (KR); DONGHEE LEE, Yongin-si (KR); TAEKJOON LEE, Yongin-si (KR); JUNEHYUK JUNG, Yongin-si (KR)

(21) Appl. No.: 18/883,409

(22) Filed: Sep. 12, 2024

(30) Foreign Application Priority Data
Sep. 27, 2023 (KR) 10-2023-0130009

(51) Int. Cl. C09K 11/62; C09K 11/02; C09K 11/58

(52) U.S. Cl. CPC C09K 11/621; C09K 11/02; C09K 11/582; C09K 11/623

(57) ABSTRACT

A quantum dot includes a core containing a first semiconductor nanocrystal, a first shell around (e.g., surrounding) the core and containing a second semiconductor nanocrystal different from the first semiconductor nanocrystal, and a second shell around (e.g., surrounding) the first shell and containing a third semiconductor nanocrystal different from the first semiconductor nanocrystal and the second semiconductor nanocrystal, wherein the core has a band gap of about 1.5 eV to about 3.3 eV, a band gap of the second shell is greater than a band gap of the core and is about 3.54 eV or less, and a band gap of the first shell is greater than a band gap of the core and smaller than a band gap of the second shell.

### CROSS-REFERENCE TO RELATED APPLICATION

The present application claims priority to and the benefit of Korean Patent Application No. 10-2023-0130009, filed on Sep. 27, 2023, the entire content of which is hereby incorporated by reference.

### BACKGROUND

### 1. Field

Embodiments of the present disclosure relate to a quantum dot, a light emitting element, and a display device, and for example, to a quantum dot, a light emitting element including the quantum dot, and a display device including the quantum dot.

### 2. Description of the Related Art

Various types (kinds) of display devices used for multimedia electronic devices such as televisions, mobile phones, tablets, navigation systems, and/or game consoles are being developed. Such display devices include so-called self-luminescent light emitting elements configured to accomplish display (e.g., of an image) by causing light emitting materials of the emitting elements to emit light.

Among the light emitting elements, quantum dot light emitting elements that include quantum dots in an emission layer are capable of providing relatively high color purity, high luminous efficiency, and multicolor light emission compared to other comparable display devices. In order to maintain such excellent or desire light emission quality, research is ongoing into emission layer materials of the emission layer.

### SUMMARY

Aspects of one or more embodiments of the present disclosure are directed toward a quantum dot having satisfactory quantum yield characteristics and improved light stability and color reproducibility.

Aspects of one or more embodiments of the present disclosure also are directed toward a light emitting element having satisfactory quantum yield characteristics and improved light stability and color reproducibility and thus exhibiting excellent or desire light emitting properties.

Aspects of one or more embodiments of the present disclosure also are directed toward a display device including a quantum dot and thus having excellent or desire display quality characteristics.

Additional aspects will be set forth in part in the description which follows and, in part, will be apparent from the description, or may be learned by practice of the presented embodiments of the disclosure.

One or more embodiments of the present disclosure provides a quantum dot including a core containing a first semiconductor nanocrystal, a first shell around (e.g., surrounding) the core and containing a second semiconductor nanocrystal different from the first semiconductor nanocrystal, and a second shell around (e.g., surrounding) the first shell and containing a third semiconductor nanocrystal different from the first semiconductor nanocrystal and the second semiconductor nanocrystal. The first semiconductor nanocrystal may include a Group I-III-VI compound, the second semiconductor nanocrystal may include at least one of a Group I-III-VI compound or a Group II-III-VI compound, and the third semiconductor nanocrystal may include a Group II-VI compound. The core may have a band gap of about 1.5 eV to about 3.3 eV, a band gap of the second shell may be greater than the band gap of the core and may be about 3.54 eV or less, and a band gap of the first shell may be greater than the band gap of the core and smaller than the band gap of the second shell.

In one or more embodiments, the core may include copper, indium, gallium, and sulfur.

In one or more embodiments, the first shell may have the same crystal structure as the core.

In one or more embodiments, the first shell may satisfy Equation 1:

$$SH 1 ( Å ) = CO ( Å ) \pm 0.2 Å \qquad Equation 1$$

In Equation 1 above, SH1 is a lattice constant of the first shell and CO is a lattice constant of the core.

In one or more embodiments, the second semiconductor nanocrystal may include the Group I-III-VI compound and the Group II-III-VI compound, the Group I-III-VI compound of the first shell may be selected from among a ternary compound selected from the group consisting of a compound containing Ag—In—S, a compound containing Ag—Ga—S, a compound containing Ag—Al—S, a compound containing Ag—In—Se, a compound containing Ag—Ga—Se, a compound containing Ag—Al—Se, a compound containing Cu—In—S, a compound containing Cu—Ga—S, a compound containing Cu—Al—S, a compound containing Cu—In—Se, a compound containing Cu—Ga—Se, a compound containing Cu—Al—Se, and/or a (e.g., any suitable) mixture thereof; and a quaternary compound selected from the group consisting of a compound containing Ag—In—Ga—S, a compound containing Ag—Ga—Se—S, and/or a (e.g., any suitable) mixture thereof. The Group II-III-VI compound of the first shell may be selected from the group consisting of a ternary compound selected from the group consisting of a compound containing Zn—In—S, a compound containing Zn—Ga—S, a compound containing Zn—Al—S, a compound containing Zn—In—Se, a compound containing Zn—Ga—Se, a compound containing Zn—Al—Se, a compound containing Mg—In—S, a compound containing Mg—Ga—S, a compound containing Mg—Al—S, a compound containing Mg—In—Se, a compound containing Mg—Ga—Se, a compound containing Mg—Al—Se, and/or a (e.g., any suitable) mixture thereof; and a quaternary compound selected from the group including (e.g., consisting of) a compound containing Zn—In—Ga—S, a compound containing Zn—In—Se—S, and/or a (e.g., any suitable) mixture thereof.

In one or more embodiments, the first shell may include the Group II-III-VI compound, and in the Group II-III-VI compound, a gallium atom may be included as a Group III element.

In one or more embodiments, the first shell may include zinc, gallium, and sulfur.

In one or more embodiments, the second shell may include at least one of MgO, MgS, MgSe, MgTe, ZnO, ZnS, ZnSe, or ZnTe.

In one or more embodiments, the second shell may include ZnS.

In one or more embodiments, the quantum dot may have a diameter of about 2 nm to about 10 nm.

In one or more embodiments, the quantum dot may have a full width of half maximum of about 65 nm or less.

In one or more embodiments, the quantum dot may have a central emission wavelength of about 380 nm to about 800 nm.

In one or more embodiments of the present disclosure, a light emitting element includes a first electrode, a second electrode facing (opposite) the first electrode, an emission layer between the first electrode and the second electrode and including a quantum dot, and a functional layer between the emission layer and the first electrode and/or between the emission layer and the second electrode. The quantum dot included in the emission layer may be the quantum dot of one or more embodiments described above.

In one or more embodiments, the functional layer may include a hole transport region below the emission layer, and an electron transport region above the emission layer.

In one or more embodiments of the present disclosure, a display device includes a circuit layer, and a display element layer on the circuit layer and including a light emitting element and a pixel defining film in which a pixel opening is defined, and as the light emitting element, the light emitting element of one or more embodiments described above may be used.

### BRIEF DESCRIPTION OF THE FIGURES

The accompanying drawings are included to provide a further understanding of the present disclosure, and are incorporated in and constitute a part of this specification. The drawings illustrate one or more embodiments of the present disclosure and, together with the description, serve to explain aspects, features, and/or principles of the present disclosure. In the drawings:

FIG. 1 is a perspective view of an electronic device according to one or more embodiments of the present disclosure;

FIG. 2 is an exploded perspective view of an electronic device according to one or more embodiments of the present disclosure;

FIG. 3 is a cross-sectional view of a display device taken along the line I-I′, according to one or more embodiments of the present disclosure;

FIG. 4 is a plan view of a display device according to one or more embodiments of the present disclosure;

FIG. 5 is a cross-sectional view of a display device taken along the line II-II′, according to one or more embodiments of the present disclosure;

FIG. 6A is a cross-sectional view showing a light emitting element according to one or more embodiments of the present disclosure;

FIG. 6B is a cross-sectional view showing a light emitting element according to one or more embodiments of the present disclosure;

FIG. 7 is a view schematically showing a structure of a quantum dot according to one or more embodiments of the present disclosure;

FIG. 8A is a view showing a photoluminescence (PL) spectrum of quantum dots of a Comparative Example;

FIG. 8B is a view showing a photoluminescence (PL) spectrum of quantum dots of an Example; and

FIG. 9 shows the results of evaluating light stability of Examples and Comparative Examples.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Further, the embodiments included herein are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In addition, it will also be understood that when an element is referred to as being “between” two elements, it can be the only element between the two elements, or one or more intervening elements may also be present.

Unless otherwise noted, like numbers refer to like elements throughout, and duplicative descriptions thereof may not be provided. In addition, in the drawings, the thickness, the ratio, and the dimensions of elements may be exaggerated for clarity and/or for an effective description of the technical contents.

As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof.

As used herein, being “disposed directly on” may mean that there is no additional layer, film, region, plate, or the like between a part and another part, such as a layer, a film, a region, a plate, and/or the like. For example, being “disposed directly on” may mean that two layers or two members are disposed without using an additional member such as an adhesive member, therebetween.

As used herein, the terms “use,” “using,” and “used” may be considered synonymous with the terms “utilize,” “utilizing,” and “utilized,” respectively.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the term “Group” refers to a group the IUPAC Periodic Table of Elements.

As used herein, “Group I” may include Group IA elements and Group IB elements. For example, the Group I elements may be copper (Cu), but are not limited thereto.

As used herein, “Group II” may include Group IIA elements and Group IIB elements. For example, the Group II elements may be magnesium (Mg) or zinc (Zn), but are not limited thereto.

As used herein, “Group III” may include Group IIIA elements and Group IIIB elements. For example, the Group III elements may be aluminum (Al), indium (In), or gallium (Ga) but are not limited thereto.

As used herein, “Group V” may include Group VA elements and Group VB elements. For example, the Group V elements may be phosphorus (P), arsenic (As), or antimony (Sb), but are not limited thereto.

As used herein, “Group VI” may include Group VIA elements and Group VIB elements. For example, the Group VI elements may be oxygen (O), sulfur(S), selenium (Se) or tellurium (Te), but are not limited thereto.

In the present disclosure, when particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

Unless otherwise defined, all terms (including technical and scientific terms) used herein have the same meaning as commonly understood by one of ordinary skill in the art to which the present disclosure pertains. It will be further understood that terms, such as those defined in commonly used dictionaries, should be interpreted as having a meaning that is consistent with their meaning in the context of the relevant art and/or the specification and should not be interpreted in an idealized or overly formal sense, unless expressly so defined herein.

Hereinafter, a quantum dot, a light emitting element, and a display device including the same according to embodiments of the present disclosure will be described with reference to the accompanying drawings.

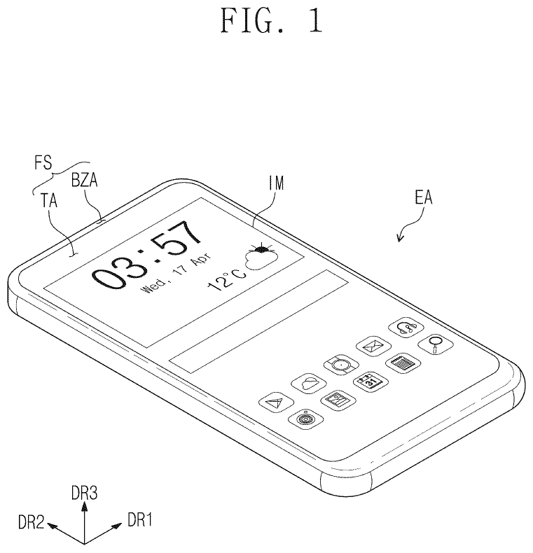

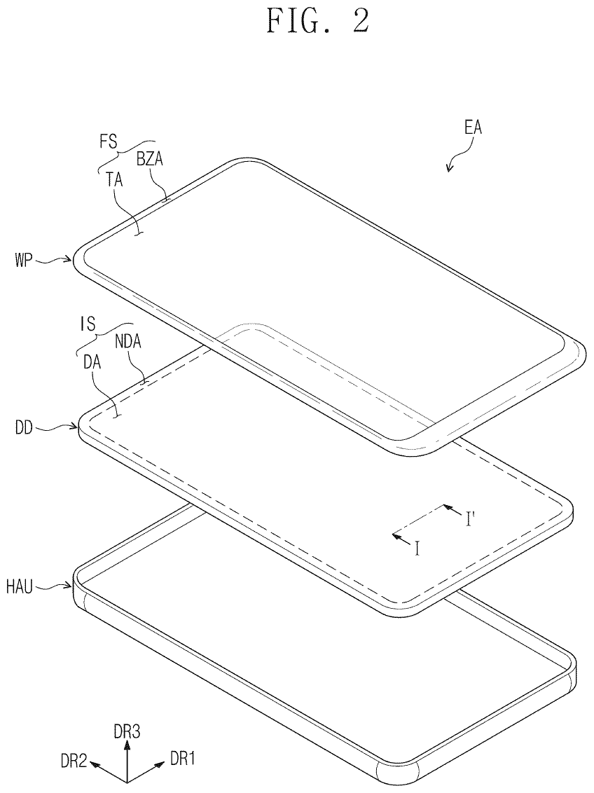

FIG. 1 is a perspective view showing an electronic device EA according to one or more embodiments of the present disclosure. FIG. 2 is an exploded perspective view of the electronic device EA according to one or more embodiments of the present disclosure.

In one or more embodiments, the electronic device EA may be a large-sized electronic device such as a television set, a monitor, or an outdoor billboard. In one or more embodiments, the electronic device EA may be a small- and medium-sized electronic device such as a personal computer, a laptop computer, a personal digital terminal, a car navigation unit, a game console, a smartphone, a tablet, and/or a camera. These devices are merely provided as examples, and other electronic devices may be employed as long as they do not depart from the spirit and scope of the present disclosure. In FIG. 1, as an example, a smartphone is shown as the electronic device EA.

In one or more embodiments, the electronic device EA may include a foldable display device having a folding region and a non-folding region, or a bending display device having at least one bending portion.

The front surface FS in the electronic device EA may correspond to a front surface of the display device DD and may correspond to a front surface of a window WP. Accordingly, a reference symbol FS will be used all for the front surface of the electronic device EA, the front surface of the display device DD, and the front surface of the window WP.

Users may view images IM provided through the transmission region TA corresponding to the front surface FS of the electronic device EA. The image IM may include still images as well as dynamic images. FIG. 1 shows that the front surface FS is parallel to a plane defined by a first direction DR1 and a second direction DR2 crossing the first direction DR1. However, this is merely an example, and the front surface FS of the electronic device EA in one or more embodiments may have a curved shape.

Herein, the term “plane” refers to a plane defined by the first direction DR1 and the second direction DR2, and the term “cross-section” refers to a plane normal (e.g., perpendicular) to the plane defined by the first direction DR1 and the second direction DR2 and parallel to a third direction DR3. A thickness direction of the electronic device EA may be parallel to the third direction DR3 which is a normal direction with respect to a plane defined by the first direction DR1 and the second direction DR2. Among the thickness directions of the electronic device EA, a direction in which the image IM is displayed is indicated by the third direction DR3. A front surface (or an upper surface) and a rear surface (or a lower surface) of respective members may be defined by the third direction DR3.

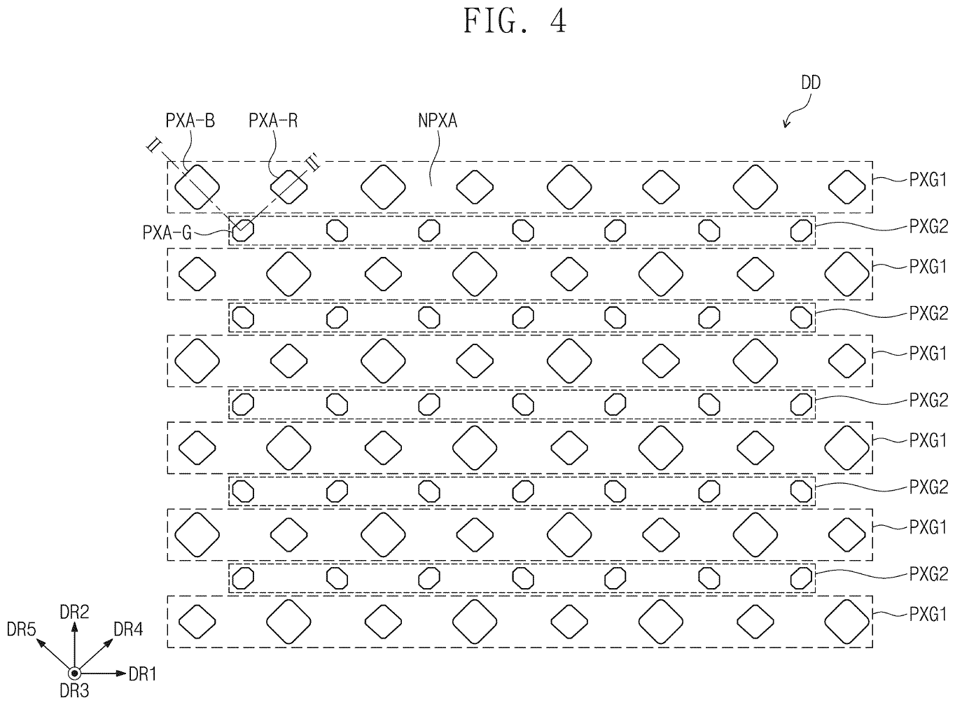

A fourth direction DR4 (see, e.g., FIG. 4) may be a direction between the first direction DR1 and the second direction DR2. A fifth direction DR5 may cross the fourth direction DR4 and may be inclined with respect to the second direction DR2. The fourth direction DR4 and the fifth direction DR5 may be positioned on a plane parallel to the plane defined by the first direction DR1 and the second direction DR2. The directions indicated by the first to fifth directions DR1, DR2, DR3, DR4, and DR5 are relative concepts, and may thus be changed to other directions.

Herein, when a component is “directly disposed/directly arranged/directly formed” on another component, it indicates that a third component is not disposed between the component and the other component. That is, when a component is “directly placed/directly arranged/directly formed” on another component, it indicates that the component is in “contact” with the other component.

Referring to FIGS. 1 and 2, the electronic device EA may include a window WP, a display device DD, and a housing HAU. The window WP may be arranged above the display device DD. The housing HAU may be arranged below the display device DD. The display device DD may be arranged between the window WP and the housing HAU.

The window WP may include an optically transparent insulating material. The window WP may include a transmission region TA and a bezel region BZA. A front surface FS of the window WP including the transmission region TA and the bezel region BZA corresponds to a front surface FS of the electronic device EA. The transmission region TA may be an optically transparent region. In FIGS. 1 and 2, the transmission region TA is shown in a rectangular shape with rounded corners. However, this is presented as an example, and the transmission region TA may have one or more suitable shapes and is not limited to any one embodiment.

The bezel region BZA may be a region having a relatively lower light transmittance than the transmission region TA. The bezel region BZA may have a set or predetermined color. The bezel region BZA may be adjacent to the transmission region TA and may be around (e.g., surround) the transmission region TA. The bezel region BZA may define the shape of the transmission region TA. However, the present disclosure is not limited to what is shown, and the bezel region BZA may be arranged adjacent to only one side of the transmission region TA, and a portion thereof may not be provided.

In one or more embodiments, the display device DD may be substantially configured to generate an image IM. The display device DD may be arranged below the window WP. As used herein, “below” may indicate a direction opposite to the direction in which the display device DD provides the image IM.

The display device DD may display the image IM through a display surface IS. The display surface IS may be parallel to a plane defined by the first direction DR1 and the second direction DR2. The display surface IS may include a display region DA and a non-display region NDA.

The display region DA may be a region activated according to electrical signals. The non-display region NDA may be a region covered by the bezel region BZA. The non-display region NDA may be adjacent to the display region DA. The non-display region NDA may be around (e.g., surround) the display region DA. However, the present disclosure is not limited thereto, and the non-display region NDA may not be provided, or the non-display region NDA may be arranged only on one or more sides of the display region DA.

The housing HAU may accommodate the display device DD. The housing HAU may be arranged to cover the display device DD while exposing the display surface IS that is a top surface of the display device DD. The housing HAU may cover side surfaces and a bottom surface of the display device DD, and expose the entire top surface. However, the present disclosure is not limited thereto, and the housing HAU may cover a portion of the top surface as well as the side surfaces and the bottom surface of the display device DD.

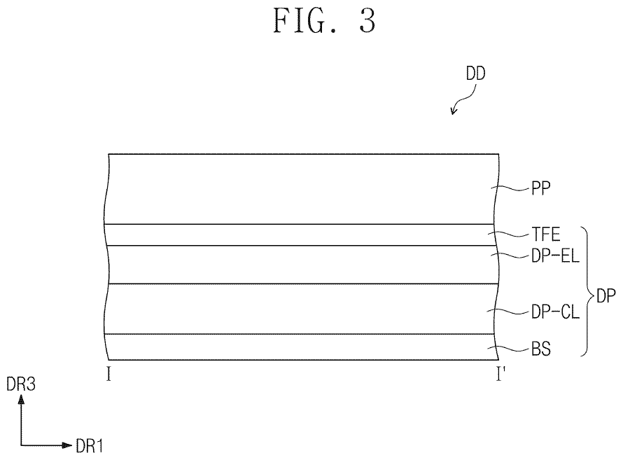

FIG. 3 is a cross-sectional view of the display device DD according to one or more embodiments of the present disclosure. FIG. 3 may be a cross-sectional view of the display device DD taken along the line I-I′ of FIG. 2, according to one or more embodiments of the present disclosure.

Referring to FIG. 3, the display device DD may include a display panel DP and a light control layer PP arranged on the display panel DP. The display panel DP may include a base substrate BS, a circuit layer DP-CL, and a display element layer DP-EL. In one or more embodiments, the display panel DP may include an encapsulation layer TFE arranged on the display element layer DP-EL.

In the display device DD of one or more embodiments, the display panel DP may be a light emitting display panel. For example, the display panel DP may be a quantum dot light emitting display panel including a quantum dot light emitting element. However, the present disclosure is not limited thereto.

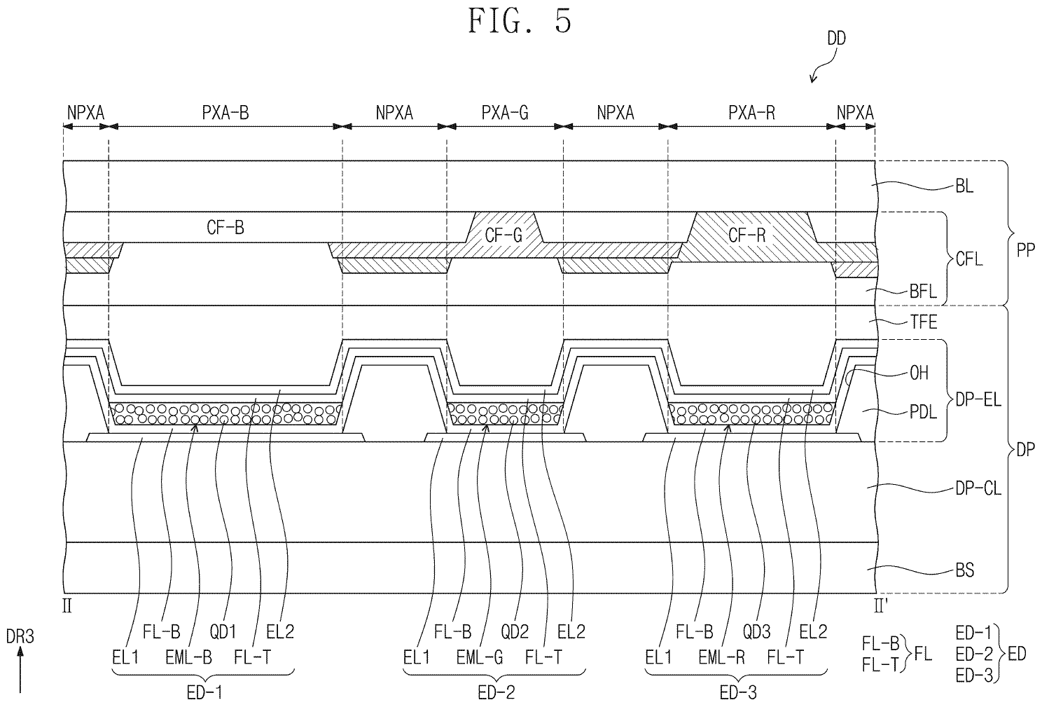

The display panel DP may include a base substrate BS, a circuit layer DP-CL arranged on the base substrate BS, and a display element layer DP-EL arranged on the circuit layer DP-CL. The element device layer DP-EL may include a light emitting element ED (see, e.g., FIG. 5). The encapsulation layer TFE may be directly arranged on the display element layer DP-EL or may be bonded to the display element layer DP-EL through a separate member.

The light control layer PP may be arranged on the display panel DP to control light reflected in the display panel DP due to external light. The light control layer PP may be a reflection reduction layer reducing reflectance of external light. For example, the light control layer PP may include a polarizing film (or a polarizing layer) including a phase retarder and/or a polarizer, multi-layered reflection layers that induce destructive interference of reflected light, or color filters arranged corresponding to the pixel arrangement and light emitting color of the display panel DP. When the light control layer PP includes the color filters, the color filters may be arranged in consideration of the light emitting colors of pixels included in the display panel DP. In one or more embodiments, the light control layer PP may not be provided.

FIG. 4 is a plan view of the display device DD according to one or more embodiments of the present disclosure. FIG. 5 is a cross-sectional view showing the display device DD of one or more embodiments of the present disclosure. FIG. 5 is a cross-sectional view of the display device DD taken along the line II-II′ of FIG. 4, according to one or more embodiments of the present disclosure.

Referring to FIGS. 4 and 5, the display device DD may include a plurality of light emitting regions PXA-B, PXA-G, and PXA-R, which are repeatedly arranged (with each other) throughout the display region DA (see, e.g., FIG. 2). The display device DD of one or more embodiments may include first to third light emitting regions PXA-B, PXA-G, and PXA-R, which are distinct from one another. In one or more embodiments, the display device DD may have a peripheral region NPXA arranged around (e.g., around each of) the first to third light emitting regions PXA-B, PXA-G, and PXA-R. The peripheral region NPXA sets boundaries between the first to third light emitting regions PXA-B, PXA-G, and PXA-R. The peripheral region NPXA may be around (e.g., surround) the first to third light emitting regions PXA-B, PXA-G, and PXA-R. A structure that prevents (or protects from) color mixing between the first to third light emitting regions PXA-B, PXA-G, and PXA-R, for example, a pixel defining film PDL may be arranged in the peripheral region NPXA.

The pixel defining film PDL may define light emitting regions PXA-B, PXA-G, and PXA-R. The light emitting regions PXA-B, PXA-G, and PXA-R and the peripheral region NPXA may be separated by the pixel defining film PDL.

The display panel DP according to one or more embodiments may include a plurality of light emitting elements ED-1, ED-2, and ED-3, which emit light in different wavelength ranges. The plurality of light emitting elements ED-1, ED-2, and ED-3 may be to emit light of different colors. For example, the display panel DP may include a first light emitting element ED-1 emitting blue light, a second light emitting element ED-2 emitting green light, and a third light emitting element ED-3 emitting red light. However, the present disclosure is not limited thereto, and the first to third light emitting elements ED-1, ED-2 and ED-3 may be to emit light in substantially the same wavelength range or at least one of the three may be to emit light in a different wavelength range.

The light emitting regions PXA-B, PXA-G, and PXA-R may each be a region emitting light generated from one of light emitting elements ED-1, ED-2, and ED-3, respectively. FIGS. 4 and 5 show first to third light emitting regions PXA-B, PXA-G, and PXA-R, which emit blue light, green light, and red light, respectively. For example, the display device DD of one or more embodiments may include a first light emitting region PXA-B emitting blue light, a second light emitting region PXA-G emitting green light, and a third light emitting region PXA-R emitting red light, which are separated.

In the display device DD of one or more embodiments shown in FIGS. 4 and 5, the light emitting regions PXA-B, PXA-G and PXA-R may have different sizes (e.g., areas) according to the color emitted from the emission layers EML-B, EML-G, and EML-R of the light emitting elements ED-1, ED-2 and ED-3. FIG. 4 shows, as an example, the first to third light emitting regions PXA-B, PXA-G, and PXA-R having different planar areas, but the present disclosure is not limited thereto.

The first light emitting region PXA-B corresponding to the first light emitting element ED-1 emitting blue light may have the largest area, and the second light emitting region PXA-G corresponding to the second light emitting element ED-2 emitting green light may have the smallest area. However, the present disclosure is not limited thereto, and the first to third light emitting regions PXA-B, PXA-G, and PXA-R may be to emit light of colors other than blue light, green light, and red light. In one or more embodiments, the first to third light emitting regions PXA-B, PXA-G, and PXA-R may have the same area, or may be provided with area ratios different from what shown in FIG. 4. The areas of the first to third light emitting regions PXA-B, PXA-G, and PXA-R may be set according to the color of emitted light. In this case, the areas may be areas when viewed on a plane (e.g., in a plan view).

The first light emitting region PXA-B and the third light emitting region PXA-R may be alternately arranged in the first direction DR1 to form a first group PXG1. The second light emitting region PXA-G may be arranged in the first direction DR1 to form a second group PXG2. The first group PXG1 may be spaced and/or apart (e.g., spaced apart or separated) from the second group PXG2 in the second direction DR2. The first group PXG1 and the second group PXG2 may each be provided in plurality. The first groups PXG1 and the second groups PXG2 may be alternately arranged in the second direction DR2.

One third light emitting region PXA-R may be spaced and/or apart (e.g., spaced apart or separated) from one second light emitting region PXA-G in the fourth direction DR4. One first light emitting region PXA-B may be spaced and/or apart (e.g., spaced apart or separated) from one second light emitting region PXA-G in the fifth direction DR5.

In one or more embodiments, the arrangement structure of the light emitting regions PXA-B, PXA-G and PXA-R is not limited to the arrangement structure shown in FIG. 4. For example, in the light emitting regions PXA-B, PXA-G, and PXA-R, the first light emitting region PXA-B, the second light emitting region PXA-G, and the third light emitting region PXA-R may be arranged sequentially and alternately along the first direction DR1. In one or more embodiments, the shapes of the light emitting regions PXA-B, PXA-G, and PXA-R when viewed on a plane (e.g., in a plan view) are not limited to what is shown, and may be defined as shapes different from what is shown.

Referring to FIG. 5, the display device DD may include a display panel DP and a light control layer PP, which are stacked in the third direction DR3. The display panel DP may include a base substrate BS, a circuit layer DP-CL provided on the base substrate BS, a display element layer DP-EL, and an encapsulation layer TFE. The display element layer DP-EL may include a light emitting element ED arranged between the pixel defining films PDLs or on the pixel defining film PDL. The encapsulation layer TFE may be arranged on the display element layer DP-EL and may thus cover the light emitting element ED.

The base substrate BS may be a member providing a base surface on which the display element layer DP-EL is arranged. The base substrate BS may be a glass substrate, a metal substrate, a plastic substrate, and/or the like. However, the present disclosure is not limited thereto, and the base substrate BS may be an inorganic layer, an organic layer, or a complex material layer.

The base substrate BS may include a single-layered or multi-layered structure. For example, the base substrate BS may include a first synthetic resin layer, a multi-layered or single-layered intermediate layer, and a second synthetic resin layer, which are sequentially stacked. The intermediate layer may be referred to as a base barrier layer. The intermediate layer may include a silicon oxide (SiOₓ) layer and an amorphous silicon (a-Si) layer arranged on the silicon oxide layer, but the present disclosure is not particularly limited thereto. For example, the intermediate layer may include at least one of a silicon oxide layer, a silicon nitride layer, a silicon oxynitride layer, or an amorphous silicon layer. The base substrate BS may be a flexible substrate that may be readily bent or folded.

The first and second synthetic resin layers may each include a polyimide-based resin. In one or more embodiments, the first and second synthetic resin layers may each include at least one selected from among an acrylic-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. As used herein, a “˜˜-based” resin may be considered as including a functional group of “˜˜”.

In one or more embodiments, the circuit layer DP-CL may be arranged on the base substrate BS, and the circuit layer DP-CL may include a plurality of transistors. The transistors may each include a control electrode, an input electrode, and an output electrode. For example, the circuit layer DP-CL may include a switching transistor and a driving transistor for driving the light emitting element ED of the display element layer DP-EL.

The display element layer DP-EL may be arranged on the circuit layer DP-CL. The display element layer DP-EL may include a pixel defining film PDL and first to third light emitting elements ED-1, ED-2, and ED-3, which are divided (separated) by the pixel defining film PDL. The light emitting elements ED-1, ED-2, and ED-3 of the display element layer DP-EL may be electrically connected to driving elements of the circuit layer DP-CL, and may thus generate light according to signals provided by the driving elements to display images.

The encapsulation layer TFE may be arranged on the display element layer DP-EL. The encapsulation layer TFE may serve to protect the light emitting element layer DP-EL from moisture, oxygen, and/or foreign substances such as dust particles. The encapsulation layer TFE may seal the light emitting elements ED of the display element layer DP-EL. The encapsulation layer TFE may include at least one thin film for improving optical efficiency of the display element layer DP-EL or protecting the display element layer DP-EL. The encapsulation layer TFE may include at least one inorganic layer. The encapsulation layer TFE may include a stack structure in which an inorganic layer, an organic layer, and an inorganic layer are sequentially stacked.

The pixel defining film PDL may be formed of a polymer resin. For example, the pixel defining film PDL may be formed including a polyacrylate-based resin or a polyimide-based resin. In one or more embodiments, the pixel defining film PDL may be formed by further including an inorganic material in addition to the polymer resin. In one or more embodiments, the pixel defining film PDL may be formed including a light absorbing material, or may be formed including a black pigment and/or a black dye. The pixel defining film PDL formed including a black pigment and/or a black dye may implement a black pixel defining film. When forming the pixel defining film PDL, carbon black may be used as a black pigment and/or a black dye, but the present disclosure is not limited thereto.

In one or more embodiments, the pixel defining film PDL may be formed of an inorganic material. For example, the pixel defining film PDL may be formed of an inorganic material such as silicon nitride (SiₓN_{y}), e.g., Si₃N₄, silicon oxide (SiOₓ), e.g., SiO₂, and/or silicon oxynitride (SiOₓN_{y}).

The pixel defining film PDL may have a pixel opening OH (e.g., pixel openings OH) defined therein. A portion of a first electrode EL1 may be exposed in the pixel opening OH. Portions corresponding to the first electrode EL1 exposed in the pixel opening OH may be defined as light emitting regions PXA-B, PXA-G, and PXA-R. However, the present disclosure is not limited thereto.

The pixel defining film PDL may separate the first to third light emitting elements ED-1, ED-2, and ED-3. The emission layers EML-B, EML-G, and EML-R of the light emitting elements ED-1, ED-2 and ED-3 may be arranged and separated in the pixel openings OH defined by the pixel defining film PDL.

The first to third light emitting elements ED-1, ED-2, and ED-3 may each include a first electrode EL1, a second electrode EL2 facing (opposite) the first electrode EL1, emission layers EML-B, EML-G, and EML-R arranged between the first electrode EL1 and the second electrode EL2, and a functional layer FL arranged between the first electrode EL1 and the second electrode EL2. The functional layer FL may be arranged either between the first electrode EL1 and the emission layers EML-B, EML-G, and EML-R or between the emission layers EML-B, EML-G, and EML-R and the second electrode EL2 or both. For example, the first to third light emitting elements ED-1, ED-2, and ED-3 may each include a first electrode EL1, a first functional layer FL-B, one or the emission layers EML-B, EML-G, and EML-R, a second functional layer FL-T, and a second electrode EL2, which are sequentially stacked in the third direction DR3.

The first electrode EL1 may be exposed in the pixel opening OH of the pixel defining film PDL. The first electrode EL1 has conductivity (e.g., is a conductor). The first electrode EL1 may be formed of a metal material, a metal alloy or a conductive compound. The first electrode EL1 may be an anode or a cathode. However, the present disclosure is not limited thereto.

In one or more embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/AI (a stack structure of LiF and Al), Mo, Ti, W, a compound thereof, and/or a (e.g., any suitable) mixture thereof (e.g., a mixture of Ag and Mg). In one or more embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the first electrode EL1 may have a three-layer structure of ITO/Ag/ITO, but the present disclosure is not limited thereto. In one or more embodiments, the first electrode EL1 may include the above-described metal materials, a combination of two or more metal materials selected from among the above-described metal materials, or oxides of the above-described metal materials; however, the present disclosure is not limited thereto. The first electrode EL1 may have a thickness of about 700 Angstroms (Å) to about 10000 Å. For example, the first electrode EL1 may have a thickness of 1000 Å to about 3000 Å.

The second electrode EL2 may be arranged on the first electrode EL1. The second electrode EL2 may be a cathode or an anode. In one or more embodiments, if (e.g., when) the first electrode EL1 is an anode, the second electrode EL2 may be a cathode, and if (e.g., when) the first electrode EL1 is a cathode, the second electrode EL2 may be an anode. The second electrode EL2 may be a common electrode. However, the present disclosure is not limited thereto.

The second electrode EL2 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, a compound thereof, and/or a (e.g., any suitable) mixture thereof (e.g., AgMg, AgYb, or MgYb). In one or more embodiments, the second electrode EL2 may have a multilayer structure including a reflective film or a transflective film formed of the above-described materials, and/or a transparent conductive film formed of indium tin oxide (ITO), indium zinc oxide (IZO), zinc oxide (ZnO), indium tin zinc oxide (ITZO), and/or the like. For example, the second electrode EL2 may include the above-described metal materials, a combination of two or more metal materials selected from among the above-described metal materials, or one or more oxides of the above-described metal materials.

In one or more embodiments, the second electrode EL2 may be connected with an auxiliary electrode. When the second electrode EL2 is connected with the auxiliary electrode, the resistance of the second electrode EL2 may decrease.

Emission layers EML-B, EML-G, and EML-R may be arranged between the first electrode EL1 and the second electrode EL2. The light emitting element ED of one or more embodiments may include quantum dots QD1, QD2, and QD3 in the emission layers EML-B, EML-G, and EML-R. In one or more embodiments, the display device DD may include the first to third light emitting elements ED-1, ED-2, and ED-3, and at least one of the first to third light emitting elements ED-1, ED-2, or ED-3 may include the emission layers EML-B, EML-G, and EML-R including the quantum dots QD1, QD2, and QD3 according to one or more embodiments.

The quantum dots QD1, QD2, and QD3 of one or more embodiments may each include a core and a shell around (e.g., surrounding) the core. Accordingly, the quantum dots QD1, QD2, and QD3 may each have a core-shell structure. For example, the quantum dots QD1, QD2, and QD3 may include a core and two shells around (e.g., surrounding) the core. The quantum dots QD1, QD2, and QD3 of one or more embodiments include two shells containing different semiconductor nanocrystals, of which the shell adjacent to the core has the same crystal structure as the core and a lattice constant substantially similar to that of the core, thereby keeping a narrow full width of half maximum of the core, and exhibiting high quantum yield, excellent or suitable stability, and high absorption properties. Accordingly, the light emitting element ED of one or more embodiments may exhibit excellent or suitable element characteristics and reliability.

In one or more embodiments, the display device DD including a plurality of light emitting elements ED containing the quantum dots QD1, QD2, and QD3 according to one or more embodiments may exhibit excellent or suitable display quality and reliability resulting from improved surface characteristics of the quantum dots QD1, QD2, and QD3.

The emission layers EML-B, EML-G, and EML-R may each include a plurality of quantum dots QD1, QD2, and QD3. In one or more embodiments, the emission layers EML-B, EML-G, and EML-R may be to emit light having fluorescence. For example, the quantum dots QD1, QD2, and QD3 may be used as a fluorescent dopant material.

In one or more embodiments, the first light emitting element ED-1 may include a first emission layer EML-B including a first quantum dot QD1, the second light emitting element ED-2 may include a second emission layer EML-G including a second quantum dot QD2, and the third light emitting element ED-3 may include a third emission layer EML-R including a third quantum dot QD3. In one or more embodiments, the first quantum dot QD1 may be to emit blue light, the second quantum dot QD2 may be to emit green light, and the third quantum dot QD3 may be to emit red light. However, the present disclosure is not limited thereto, and the first to third quantum dots QD1, QD2, and QD3 may be to emit light in wavelength ranges other than blue, green, and red.

The quantum dots QD1, QD2, and QD3 included in the emission layers EML-B, EML-G, and EML-R, respectively, may be stacked to form a layer. In FIG. 5, the quantum dots QD1, QD2, and QD3 having a circular cross-section are arranged to form two layers, but the present disclosure is not limited thereto. For example, the arrangement of the quantum dots QD1, QD2, and QD3 may vary depending on the thicknesses of the emission layers EML-B, EML-G, and EML-R, the shapes of the quantum dots QD1, QD2, and QD3 included in the emission layers EML-B, EML-G, and EML-R, the average diameters of the quantum dots QD1, QD2, and QD3, and/or the like. For example, in the emission layers EML-B, EML-G, and EML-R, the quantum dots QD1, QD2, and QD3 may be aligned adjacent to each other to form a single layer, or may be aligned to form a plurality of layers, such as two layers or three layers. In one or more embodiments, the emission layers EML-B, EML-G, and EML-R may further include light emitting materials in addition to the quantum dots QD1, QD2, and QD3. In one or more embodiments, the emission layers EML-B, EML-G, and EML-R may further include fluorescent or phosphorescent dopant materials, or may further include host materials.

In one or more embodiments, the first to third quantum dots QD1, QD2, and QD3 included in the light emitting elements ED-1, ED-2, and ED-3 may be formed of different core materials. In one or more embodiments, the first to third quantum dots QD1, QD2, and QD3 may be formed of the same core material, or two quantum dots selected from among the first to third quantum dots QD1, QD2, and QD3 may be formed of the same core material, and the rest may be formed of different core materials.

In one or more embodiments, the first to third quantum dots QD1, QD2, and QD3 may have different diameters. For example, the first quantum dot QD1 used in the first light emitting element ED-1 emitting light in a relatively short wavelength range may have a relatively smaller average diameter than the second quantum dot QD2 of the second light emitting element ED-2 and the third quantum dot QD3 of the third light emitting element ED-3 each emitting light in relatively long wavelength ranges. Herein, the average diameter refers to the arithmetic mean of the diameters of a plurality of quantum dot particles. Herein, the diameter of the quantum dot particles may be the average value of the width of the quantum dot particles when viewed in a cross-section view.

The relationship of the average diameters of the first to third quantum dots QD1, QD2 and QD3 is not limited to the above limitations. For example, FIG. 5 shows that the first to third quantum dots QD1, QD2, and QD3 are substantially similar in size from one another, but the first to third quantum dots QD1, QD2, and QD3 included in the light emitting elements ED-1, ED-2, and ED-3 may be different in size.

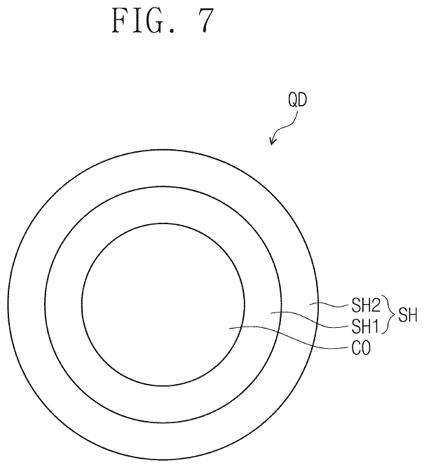

The physical or chemical properties, such as structure and material, of the quantum dots QD1, QD2, and QD3 according to one or more embodiments will be described in more detail later with reference to FIG. 7.

In the display device DD according to one or more embodiments, as shown in FIG. 5, although the thicknesses of the emission layers EML-B, EML-G, and EML-R of the first to third light emitting elements ED-1, ED-2, and ED-3 are shown to be substantially similar to one another, the present disclosure is not limited thereto. For example, in one or more embodiments, the thicknesses of the emission layers EML-B, EML-G, and EML-R of the first to third light emitting elements ED-1, ED-2, and ED-3 may be different from one another.

Any one of a first functional layer FL-B arranged between the first electrode EL1 and the emission layers EML-B, EML-G, and EML-R and/or a second functional layer FL-T arranged between the emission layers EML-B, EML-G, and EML-R and the second electrode EL2 may be a hole transport region, and the other one may be an electron transport region.

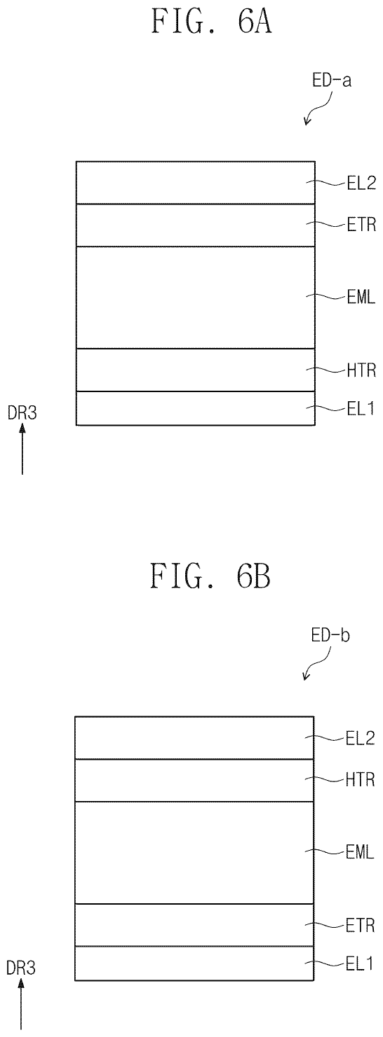

FIGS. 6A and 6B are each views showing light emitting elements ED-a and ED-b according to one or more embodiments of the present disclosure. The structure of light emitting elements ED-a and ED-b described with reference to FIGS. 6A and 6B may apply to at least one of the first to third light emitting elements ED-1, ED-2, and ED-3 shown in FIG. 5.

In FIG. 6A, the light emitting element ED-a of one or more embodiments may include a first electrode EL1, a hole transport region HTR, an emission layer EML, an electron transport region ETR, and a second electrode EL2, which are sequentially stacked along the third direction DR3. In the light emitting element ED-a of one or more embodiments, the first electrode EL1 may be an anode and the second electrode EL2 may be a cathode.

In one or more embodiments, referring to FIG. 6B, the light emitting element ED-b of one or more embodiments may include a first electrode EL1, an electron transport region ETR, an emission layer EML, a hole transport region HTR, and a second electrode EL2, which are sequentially stacked along the third direction DR3. In the light emitting element ED-b of one or more embodiments, the first electrode EL1 may be a cathode and the second electrode EL2 may be an anode.

For example, the first to third light emitting elements ED-1, ED-2, and ED-3 shown in FIG. 5 may have the stack structure of FIG. 6A or FIG. 6B. Accordingly, in the first to third light emitting elements ED-1, ED-2, and ED-3, if (e.g., when) the first functional layer FL-B is the hole transport region HTR, the second functional layer FL-T may be the electron transport region ETR, and in the first to third light emitting elements ED-1, ED-2, and ED-3, if (e.g., when) the first functional layer FL-B is the electron transport region ETR, the second functional layer FL-T may be the hole transport region HTR.

In the light emitting elements ED-a and ED-b according to one or more embodiments shown in FIGS. 6A and 6B, the hole transport region HTR may include a hole injection layer and a hole transport layer. The hole transport region HTR may have a single layer formed of a single material, a single layer formed of a plurality of different materials, or a multilayer structure having a plurality of layers formed of a plurality of different materials.

The hole transport region HTR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include one or more suitable hole injection materials and/or one or more suitable hole transport materials. For example, the hole transport region HTR may include a phthalocyanine compound such as copper phthalocyanine, N¹, N¹″-([1,1′-biphenyl]-4,4′-diyl)bis(N1-phenyl-N4, N4-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino) triphenylamine (TDATA), 4,4′,4″-tris[N (2-naphthyl)-N-phenylamino]-triphenylamine (2-TNATA), poly(3,4-ethylenedioxythiophene)/poly(4-styrenesulfonate) (PEDOT/PSS), polyaniline/Dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-I-yl)-N,N′-diphenyl-benzidine (NPB), triphenylamine-containing polyetherketone (TPAPEK), 4-isopropyl-4′-methyldiphenyliodonium tetrakis(pentafluorophenyl) borate, dipyrazino[2,3-f: 2′,3′-h]quinoxaline-2,3,6,7,10,11-hexacarbonitrile (HATCN), and/or the like.

In one or more embodiments, the hole transport region HTR may include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl) triphenylamine (TCTA), N,N′-di(1-naphtalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP), and/or the like.

The hole transport region HTR may have a thickness of about 5 nm to about 1,500 nm, for example, about 10 nm to about 500 nm. When the thickness of the hole transport region HTR satisfies the above-described ranges, satisfactory hole transport properties may be obtained without a substantial increase in driving voltage.

In the light emitting elements ED-a and ED-b according to one or more embodiments, the electron transport region ETR may include at least one of an electron transport layer or an electron injection layer, but the present disclosure is not limited thereto.

The electron transport region ETR may have a single layer formed of a single material, a single layer formed of a plurality of different materials, or a multilayer structure having a plurality of layers formed of a plurality of different materials. For example, the electron transport region ETR may have a single layer structure of an electron injection layer or an electron transport layer, and may have a single layer structure formed of an electron injection material and an electron transport material. The electron transport region ETR may have a thickness of, for example, about 20 nm to about 150 nm.

The electron transport region ETR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include one or more suitable electron injection materials and/or one or more suitable electron transport materials. For example, the electron transport region ETR may include an anthracene-based compound. In one or more embodiments, the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-ylphenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl) anthracene (ADN), 1,3-bis[3,5-di(pyridin-3-yl)phenyl]benzene (BmPyPhB), and/or a (e.g., any suitable) mixture thereof. In one or more embodiments, the electron transport region ETR may include 2,9-dimethyl-4,7-diphenyl-1,10-phenanthroline (BCP), diphenyl(4-(triphenylsilyl)phenyl)phosphine oxide (TSPO1), 4,7-diphenyl-1,10-phenanthroline (Bphen), and/or the like.

Referring to FIG. 5, the first functional layer FL-B and the second functional layer FL-T may be provided as a common layer throughout the light emitting regions PXA-B, PXA-G, and PXA-R. In one or more embodiments, the functional layer FL may overlap both the emission layers EML-B, EML-G, and EML-R and the pixel defining film PDL. However, the present disclosure is not limited to thereto, and at least one of the first functional layer FL-B or the second functional layer FL-T may overlap the emission layers EML-B, EML-G, and EML-R, and may be patterned and provided to be arranged in a pixel opening OH.

Referring to FIG. 5, the display device DD of one or more embodiments includes a light control layer PP arranged on the display panel DP. The light control layer PP may include a base layer BL and a color filter layer CFL.

The base layer BL may be a member providing a base surface on which the color filter layer CFL is arranged. The base layer BL may be a glass substrate, a metal substrate, a plastic substrate, and/or the like. However, the present disclosure is not limited thereto, and the base layer BL may be an inorganic layer, an organic layer, or a complex material layer.

The color filter layer CFL may include filters CF-B, CF-G, and CF-R. The color filter layer CFL may include first to third filters CF-B, CF-G, and CF-R. The first to third filters CF-B, CF-G, and CF-R may each be arranged to correspond to the first to third light emitting elements ED-1, ED-2, and ED-3. For example, the first filter CF-B may be a blue filter, the second filter CF-G may be a green filter, and the third filter CF-R may be a red filter. The first to third filters CF-B, CF-G, and CF-R may each be arranged to correspond to each of the first to third light emitting regions PXA-B, PXA-G, and PXA-R.

In one or more embodiments, the plurality of filters CF-B, CF-G, and CF-R that transmit different light may be arranged to overlap in an area corresponding to the peripheral region NPXA arranged between the light emitting regions PXA-B, PXA-G, and PXA-R. The plurality of filters CF-B, CF-G, and CF-R may be arranged to overlap in the third direction DR3, which is the thickness direction, to separate boundaries between the adjacent light emitting regions PXA-B, PXA-G, and PXA-R. Accordingly, the effect of blocking external light increases to serve substantially the same function as a black matrix. The overlapping structure of the plurality of filters CF-B, CF-G, and CF-R may serve to prevent or reduce color mixing.

The first to third filters CF-B, CF-G, and CF-R may each include a polymer photosensitive resin and a pigment and/or a dye. The first filter CF-B may include a blue pigment and/or a blue dye, the second filter CF-G may include a green pigment and/or a green dye, and the third filter CF-R may include a red pigment and/or a red dye. However, the present disclosure is not limited thereto, and the first filter CF-B may not include (e.g., may exclude) a pigment and/or a dye. The first filter CF-B may include a polymer photosensitive resin, but not include a pigment and/or a dye. The first filter CF-B may be transparent. The first filter CF-B may be formed of a transparent photosensitive resin.

The color filter layer CFL may further include a buffer layer BFL. For example, the buffer layer BFL may be a protection layer protecting the first to third filters CF-B, CF-G, and CF-R. The buffer layer BFL may be arranged between the display panel DP and the filters CF-B, CF-G, and CF-R. The buffer layer BFL may be arranged between the encapsulation layer TFE and the filters CF-B, CF-G, and CF-R.

The buffer layer BFL may be an inorganic material layer including at least one inorganic material among silicon nitride, silicon oxide, and/or silicon oxynitride. The buffer layer BFL may be formed of a single layer or a plurality of layers.

In one or more embodiments, the second filter CF-G and the third filter CF-R may be yellow filters. The second filter CF-G and the third filter CF-R may not be separated from each other and may be provided as a single body.

In one or more embodiments, the color filter layer CFL may further include a light blocking unit. The light blocking unit may be a black matrix. The light blocking unit may be formed including an organic light blocking material and/or an inorganic light blocking material, both or either of which may include a black pigment and/or a black dye. The light blocking unit may prevent or reduce light leakage, and separate boundaries between the adjacent filters CF-B, CF-G, and CF-R.

In one or more embodiments, the light control layer PP of the display device DD of one or more embodiments may not include (e.g., may exclude) the color filter layer CFL. The display device DD of one or more embodiments may include a polarizing layer, instead of the color filter layer CFL of the light control layer PP.

The emission layers EML-B, EML-G, EML-R, and EML of the light emitting elements ED, ED-a, and ED-a according to one or more embodiments described with reference to FIGS. 5 to 6B may include a quantum dot according to one or more embodiments of the present disclosure.

FIG. 7 is a view schematically showing a quantum dot QD of one or more embodiments the present disclosure. The description of the quantum dot QD described with reference to FIG. 7 may apply to one or more of the first to third quantum dots QD1, QD2, and QD3 shown in FIG. 5.

The quantum dot QD refers to a crystal of a semiconductor compound, and may include any material that may be to emit light of one or more suitable emission wavelengths depending on the size of the crystal or the adjusted element ratio in the quantum dot QD compound. The quantum dot QD may include semiconductor nanocrystals.

In one or more embodiments, the quantum dot QD may have a core-shell structure including a core CO and a shell SH. The quantum dot QD according to one or more embodiments, which has the core-shell structure may include a core CO containing a semiconductor nanocrystal and a shell SH around (e.g., surrounding) the core CO and containing a semiconductor nanocrystal different from that of the core CO. The shell SH of the quantum dot QD may serve as a protection layer to prevent or reduce the chemical deformation of the core CO so as to maintain semiconductor properties of the quantum dot QD, and/or a charging layer to impart electrophoresis properties to the quantum dot QD.

In one or more embodiments, the quantum dot QD may have an average diameter of about 2 nm to about 10 nm. When the diameter of the quantum dot QD satisfies the range described above, a characteristic behavior of the quantum dot QD and excellent or suitable dispersibility as well may be achieved. In one or more embodiments, if (e.g., when) the average particle diameter of the quantum dot QD is variously selected within the range as described above, the emission wavelength of the quantum dot QD and/or the semiconductor properties of the quantum dot QD may be variously changed.

Referring to FIG. 7, the quantum dot QD may include a core CO and a shell SH around (e.g., surrounding) the core CO. The shell SH may include a first shell SH1 and a second shell SH2.

The core CO may include a first semiconductor nanocrystal. The core CO is a first semiconductor nanocrystal and may include a Group I-III-VI semiconductor compound. The core CO may be a Group I-III-VI quaternary CulnGaS compound. For example, the core CO may include copper (Cu), indium (In), gallium (Ga), and sulfur(S). The core CO may be formed of copper, indium, gallium, and sulfur. The core CO may be CulnGaS₂. The quantum dot QD of one or more embodiments include the core CO containing Group I-III-VI semiconductor compounds, and may thus have a high blue light absorption rate. In one or more embodiments, the quantum dot QD may be a non-Cd-based quantum dot. For example, the core CO of the quantum dot QD may not include (e.g., may exclude) cadmium (Cd).

For example, the core CO may include copper in an amount of 1 wt % to 30 wt %, gallium in an amount of 1 wt % to 80 wt %, indium in an amount of 1 wt % to 80 wt %, and sulfur in an amount of 15 wt % to 50 wt %, with respect to 100 wt % of a total mass of the quantum dot QD. A molar ratio of the Group VI element with respect to the total moles of the Group I-III-VI semiconductor compound constituting the core CO may be about 0.3 to about 0.7, but the present disclosure is not limited thereto.

When the amounts of copper, indium, gallium, and sulfur included in the core CO are regulated within the ranges described above, the quantum dot QD of one or more embodiments may have improved color reproducibility and light absorption characteristics. The quantum dot QD includes the elements included in the core CO in the amounts within the ranges described above, and may thus emit light having a desired or suitable maximum emission wavelength. With changes in the amounts of copper, indium, gallium, and sulfur included in the core CO within the ranges described above, regulating the quantum dot QD to a desired or suitable emission wavelength may be achieved. In one or more embodiments, if (e.g., when) the amounts of elements included in the core CO are regulated within the ranges described above, the quantum dot QD may be to emit light having an emission wavelength of about 380 nm to about 800 nm. Accordingly, the quantum dot QD may be to emit blue light, green light, or red light, for example.

In one or more embodiments, the core CO may have a diameter of about 1.5 nm to about 8 nm. A large diameter of the core CO contributes to excellent or suitable light absorption characteristics and high quantum efficiency. When the average diameter of the core CO is variously selected within the ranges as described above, the emission wavelength of the quantum dot QD and/or the semiconductor properties of quantum dots may be variously changed.

The core CO including copper, indium, gallium, and sulfur may have an absorption wavelength of about 350 nm to about 530 nm. The core CO may be to absorb blue light in the wavelength ranges described above to emit blue light, green light, or red light. The emission wavelength of light emitted from the quantum dot QD may be controlled or selected by regulating the size of the core CO, the thickness of the first shell SH1, and the second shell SH2, and/or the like.

In one or more embodiments, the core CO may have a band gap of about 1.5 eV to about 3.3 eV. For example, the core CO may have a band gap of about 2.0 eV. The band gap may be an energy difference between a conduction band, which is the lowest energy level where electrons are not present, and a valence band, which is the highest energy level where electrons are present. The quantum dot QD includes the core CO having a band gap of about 1.5 eV to about 3.3 eV and may thus emit blue light, green light, and/or red light having an emission wavelength of about 380 nm to about 800 nm.

The band gap of the core CO may be regulated by adjusting the size of the core CO or adjusting the element ratio of the first semiconductor nanocrystal constituting the core CO. For example, the larger the diameter of the core CO, the smaller the band gap may be, and the smaller the diameter of the core CO, the greater the band gap may be. The core CO may be to emit light of relatively long wavelength as the band gap goes down. In one or more embodiments, the core CO may be to emit light of relatively short wavelength as the band gap goes up. The quantum dot QD in one or more embodiments may regulate the band gap of the core CO in the range of about 1.5 eV to about 3.3 eV by adjusting the size of the core CO or the element ratio of the first semiconductor nanocrystal, and may thus selectively emit blue light, green light, and/or red light. In one or more embodiments, the quantum dot QD may be configured to emit white light by combining light of one or more suitable colors.

In one or more embodiments, the core CO may have a narrow full width of half maximum. For example, the core CO may have a full width of half maximum (FWHM) of an emission wavelength spectrum of about 65 nm or less. In one or more embodiments, the core CO may have a full width of half maximum (FWHM) of an emission wavelength spectrum of about 60 nm or less. For example, the core CO may have a full width of half maximum of an emission wavelength spectrum of about 62 nm.

The crystal structure of the core CO containing copper, indium, gallium, and sulfur may be a tetragonal structure. In one or more embodiments, the core CO may have a lattice constant of about 5.35 Å, but the present disclosure is not limited thereto.

In one or more embodiments, the shell SH may be around (e.g., surround) the core CO. The shell SH may have a multilayer structure formed of a plurality of different materials. The shell SH may include a first shell SH1 and a second shell SH2. The first shell SH1 may be around or entirely around (e.g., surround) the core CO, and the second shell SH2 may be around or entirely around (e.g., surround) the first shell SH1. Accordingly, a surface of the quantum dot QD may be defined by an outer surface of the second shell SH2. The first shell SH1 may be covered by the second shell SH2 and may thus not exposed to the outside of the quantum dot QD. As the quantum dot QD of one or more embodiments includes the first shell SH1 and the second shell SH2, a passivation effect for the core CO may be excellent or suitable. Accordingly, the quantum dot QD of one or more embodiments may exhibit high quantum yield properties.

The shell SH may be around (e.g., surround) the core CO and grow to have a set or predetermined thickness. The thicknesses of the first shell SH1 and the second shell SH2 are not particularly limited, and the first shell SH1 and the second shell SH2 may each be stacked to a set or predetermined thickness on the core CO such that the quantum dot QD has a diameter of about 2 nm to about 10 nm. As shown in FIG. 7, the first shell SH1 and the second shell SH2 may have substantially the same thickness. In one or more embodiments, unlike what is shown, the first shell SH1 and the second shell SH2 may have different thicknesses.

The first shell SH1 and the second shell SH2 may include semiconductor nanocrystals that are different from the semiconductor nanocrystal included in the core CO. In one or more embodiments, the first shell SH1 and the second shell SH2 may include different semiconductor nanocrystals. The first shell SH1 may include a second semiconductor nanocrystal, and the second shell SH2 may include a third semiconductor nanocrystal. The second semiconductor nanocrystal may be different from the first semiconductor nanocrystal, and the third semiconductor nanocrystal may be different from the first semiconductor nanocrystal and the second semiconductor nanocrystal.

The first shell SH1 may include at least one of a Group I-III-VI compound or a Group II-III-VI compound. The first shell SH1 may include a material corresponding to a Group I-III-VI compound, a Group II-III-VI compound, and/or a (e.g., any suitable) combination thereof. For example, the second semiconductor nanocrystal included in the first shell SH1 may be selected from among the Group I-III-VI compound, the Group II-III-VI compound, and a (e.g., any suitable) combination thereof. The second semiconductor nanocrystal included in the first shell SH1 may have a greater band gap than the first semiconductor nanocrystal included in the core CO.

In the quantum dot QD of one or more embodiments, Group III elements (e.g., gallium elements) included in the core CO is also included in the first shell SH, and the Group III elements of the first shell SH are distributed around an interface between the core CO and the first shell SH1 to prevent or reduce Group VI elements (e.g., zinc elements) of the first shell SH1 and the second shell SH2 from spreading to the core CO, and thus changes in full width of half maximum may be reduced.

The Group I-III-VI compound included in the first shell SH1 may have a greater band gap than the Group I-III-VI compound included in the core CO. The Group I-III-VI compound included in the first shell SH1 may be selected from the group consisting of a ternary compound selected from the group consisting of AgInₓS_{y} (x and y are real numbers greater than 0), AgGaₓS_{y} (x and y are real numbers greater than 0), AgAlₓS_{y} (x and y are real numbers greater than 0), AgInₓSe_{y} (x and y are real numbers greater than 0), AgGaₓSe_{y} (x and y are real numbers greater than 0), AgAlₓSe_{y} (x and y are real numbers greater than 0), CulnₓS_{y} (x and y are real numbers greater than 0), CuGaₓS_{y} (x and y are real numbers greater than 0), CuAlₓS_{y} (x and y are real numbers greater than 0), CulnₓSe_{y} (x and y are real numbers greater than 0), CuGaₓSe_{y} (x and y are real numbers greater than 0), CuAlₓSe_{y} (x and y are real numbers greater than 0), and a (e.g., any suitable) mixture thereof; and a quaternary compound selected from the group consisting of AgInₓGa_{y}S_{z} (x, y, and z are real numbers greater than 0), AgGaₓSe_{y}S_{z} (x, y, and z are real numbers greater than 0), and a (e.g., any suitable) mixture thereof.

In one or more embodiments, the Group I-III-VI compound included in the first shell SH1 may be selected from the group consisting of a ternary compound selected from the group consisting of a compound containing Ag—In—S, a compound containing Ag—Ga—S, a compound containing Ag—Al—S, a compound containing Ag—In—Se, a compound containing Ag—Ga—Se, a compound containing Ag—Al—Se, a compound containing Cu—In—S, a compound containing Cu—Ga—S, a compound containing Cu—Al—S, a compound containing Cu—In—Se, a compound containing Cu—Ga—Se, a compound containing Cu—Al—Se, and a (e.g., any suitable) mixture thereof; and a quaternary compound selected from the group consisting of a compound containing Ag—In—Ga—S, a compound containing Ag—Ga—Se—S, and a (e.g., any suitable) mixture thereof. In the Group I-III-VI compound described above, the molar ratio of the corresponding Groups is not specified and may be changed. For example, the compound containing Ag—In—S is a compound containing Ag, In, and S, and the molar ratio of Ag, In, and S is not specified and may be changed. In one or more embodiments, in the ternary compound and/or the quaternary compound, the molar ratio of elements of each Group constituting each compound is not specified and may be changed.

For example, the Group I-III-VI compound included in the first shell SH1 may be selected from the group consisting of a ternary compound selected from the group consisting of AglnS₂, AgGaS₂, AgAlS₂, AgInSe₂, AgGaSe₂, AgAISez, CulnS₂, CuGaS₂, CuAlS₂, CulnSe₂, CuGaSe₂, CuAISe₂, and a (e.g., any suitable) mixture thereof; and a quaternary compound selected from the group consisting of AgInGaS₂, AgGaSeS, and a (e.g., any suitable) mixture thereof. However, this is presented as an example, and depending on the molar ratio of the elements of the corresponding Group, the first shell SH1 may include a different type or kind of Group I-III-VI compound from the compounds described above.

In the Group I-III-VI compound, each element included in the multi-element compound, such as the ternary compound and/or the quaternary compound, may be present in particles at a substantially uniform concentration or a non-uniform (substantially non-uniform) concentration. For example, the formulae above indicate the types (kinds) of elements included in the Group I-III-VI compound, and an element ratio in the compound may be the same or different. For example, the element ratio of Group III may be the same or different, as shown in AgInxGa₁₋ₓS₂ (x is a real number greater than 0 and 1 or less). In one or more embodiments, the element ratio of Group VI may be the same or different, as shown in AgGaSe₂₋ₓSₓ (x is a real number greater than 0 and 2 or less). This is attributed to the fact that compounds at different molar ratios may be produced, which is a characteristic of multicomponent compounds.

The Group II-III-VI compound included in the first shell SH1 may be selected from the group consisting of a ternary compound selected from the group consisting of ZnInₓS_{y} (x and y are real numbers greater than 0), ZnGaₓS_{y} (x and y are real numbers greater than 0), ZnAlₓS_{y} (x and y are real numbers greater than 0), ZnInₓSe_{y} (x and y are real numbers greater than 0), ZnGaₓSe_{y} (x and y are real numbers greater than 0), ZnAlₓSe_{y} (x and y are real numbers greater than 0), MgInₓS_{y} (x and y are real numbers greater than 0), MgGaₓS_{y} (x and y are real numbers greater than 0), MgAlₓS_{y} (x and y are real numbers greater than 0), MgInₓSe_{y} (x and y are real numbers greater than 0), MgGaₓSe_{y} (x and y are real numbers greater than 0), MgAlₓSe_{y} (x and y are real numbers greater than 0), and a (e.g., any suitable) mixture thereof; and a quaternary compound selected from the group consisting of ZnInₓGa_{y}S_{z} (x, y, and z are real numbers greater than 0), ZnInₓSe_{y}S_{z} (x, y, and z are real numbers greater than 0), and a (e.g., any suitable) mixture thereof.

In one or more embodiments, the Group II-III-VI compound included in the first shell SH1 may be selected from the group consisting of a ternary compound selected from the group consisting of a compound containing Zn—In—S, a compound containing Zn—Ga—S, a compound containing Zn—Al—S, a compound containing Zn—In—Se, a compound containing Zn—Ga—Se, a compound containing Zn—Al—Se, a compound containing Mg—In—S, a compound containing Mg—Ga—S, a compound containing Mg—Al—S, a compound containing Mg—In—Se, a compound containing Mg—Ga—Se, a compound containing Mg—Al—Se, and a (e.g., any suitable) mixture thereof; and a quaternary compound selected from the group consisting of a compound containing Zn—In—Ga—S, a compound containing Zn—In—Se—S, and a (e.g., any suitable) mixture thereof. In the Group II-III-VI compound described above, the molar ratio of the corresponding Groups is not specified and may be changed. For example, the compound containing Zn—Ga—S is a compound containing Zn, Ga, and S, and the molar ratio of Zn, Ga, and S is not specified and may be changed. In one or more embodiments, in the ternary compound and the quaternary compound, the molar ratio of elements of each Group constituting each compound is not specified and may be changed.

For example, the Group II-III-VI compound included in the first shell SH1 may be selected from the group consisting of a ternary compound selected from the group consisting of ZnIn₂S₄, ZnGaS, ZnGa₂S₄, ZnAl₂S₄, ZnIn₂Se₄, ZnGa₂Se₄, ZnAl₂Se₄, MgIn₂S₄, MgGa₂S₄, MgAl₂S₄, MgIn₂Se₄, MgGa₂Se₄, MgAl₂Se₄, and a (e.g., any suitable) mixture thereof; and a quaternary compound selected from the group consisting of ZnInGaS₄, ZnIn₂SeS, and a (e.g., any suitable) mixture thereof. However, this is presented as an example, and depending on the molar ratio of the elements of the corresponding Group, the first shell SH1 may include a different type or kind of Group II-III-VI compound from the compounds described above.

In the Group II-III-VI compound, each element included in the multi-element compound, such as the ternary compound and the quaternary compound, may be present in particles at a substantially uniform concentration or a non-uniform (substantially non-uniform) concentration. For example, the formulae above indicate the types (kinds) of elements included in the Group II-III-VI compound, and an element ratio in the compound may be the same or different. For example, the element ratio of Group III may be the same or different, as shown in ZnInxGa₂₋ₓS₄ (x is a real number between 0 and 2), and ZnInxGa₂₋ₓS₄ may include ZnInGaS₄, and/or the like. In one or more embodiments, the element ratio of Group VI may be the same or different, as shown in ZnIn₂Se₄₋ₓSₓ (x is a real number between 0 and 4), and ZnIn₂Se₄₋ₓSₓ may include ZnIn₂SeS, and/or the like.

For example, the first shell SH1 may include a Group II-III-VI semiconductor compound. The first shell SH1 may include zinc (Zn), gallium (Ga), and sulfur(S). The moles of zinc, gallium, and sulfur in the first shell SH1 may be the same or different. For example, the first shell SH1 may include a Group II-III-VI semiconductor compound of ZnGaS or ZnGa₂S₄.

In one or more embodiments, the first shell SH1 may have a greater band gap than the core CO. The band gap of the first shell SH1 may be greater than a band gap of the core CO and may be smaller than a band gap of the second shell SH2. The band gap of the first shell SH1 may have a value between the band gap of the core CO and the band gap of the second shell SH2. The band gap of the first shell SH1 may be regulated by adjusting the type or kind of element of the second semiconductor nanocrystal and/or the element ratio of the second semiconductor nanocrystal included in the first shell SH1, but the present disclosure is not limited thereto.

The first shell SH1 may have a band gap of about 1.6 eV to about 3.5 eV. For example, if (e.g., when) the first shell SH1 includes zinc, gallium, and sulfur, the band gap of the first shell SH1 may be about 3.18 eV, but the present disclosure is not limited thereto. In the quantum dot QD of one or more embodiments, luminous efficiency and stability may be improved as the first shell SH1 having a greater band gap than the core CO surrounds the core CO.

In one or more embodiments, the first shell SH1 may have the same crystal structure as the core CO. For example, the first shell SH1 may include zinc, gallium, and sulfur, and may have the same crystal structure as the core CO including copper, indium, gallium, and sulfur. The crystal structure of the first shell SH1 including zinc, gallium, and sulfur may be a tetragonal structure.

In one or more embodiments, the first shell SH1 may have a level of lattice constant substantially similar to that of the core CO. For example, the lattice constant of the first shell SH1 may have a difference of about 0.2 Å or less from the lattice constant of the core CO with respect to the absolute value. The lattice constant of the first shell SH1 may satisfy Equation 1. The first shell SH1 satisfying Equation 1 may have a level of lattice constant substantially similar to that of the core CO.

$$SH 1 ( Å ) = CO ( Å ) \pm 0.2 Å \qquad Equation 1$$

In Equation 1, SH1 is a lattice constant of the first shell SH1, and CO is a lattice constant of the core CO.

For example, the first shell SH1 including zinc, gallium, and sulfur may have a lattice constant of about 5.28 Å. The first shell SH1 has the same crystal structure as the core CO and has a lattice constant substantially similar to that of the core CO, and may thus be stacked on the core CO while maintaining a narrow full width of half maximum of the core CO. For example, the core CO including copper, indium, gallium, and sulfur may have a full width of half maximum of about 63 nm, and if (e.g., when) the first shell SH1 including zinc, gallium, and sulfur is around (e.g., surrounds) the core CO, the quantum dot QD of one or more embodiments may have a full width of half maximum of about 65 nm or less. As such, the quantum dot QD of one or more embodiments may achieve excellent or suitable color reproducibility due to a small change in the full width of half maximum if (e.g., when) the first shell SH1 is introduced into the core CO.

The second shell SH2 may include a third semiconductor nanocrystal. The second shell SH2 may include a material corresponding to the Group II-VI compound and/or a (e.g., any suitable) combination thereof. The third semiconductor nanocrystal may be selected from among the Group II-VI compound and/or a (e.g., any suitable) combination thereof. The third semiconductor nanocrystal included in the second shell SH2 may have a greater band gap than the first semiconductor nanocrystal and the second semiconductor nanocrystal.

In one or more embodiments, the Group II-VI compound included in the second shell SH2 may have a greater band gap than the second semiconductor nanocrystal included in the first shell SH1. The Group II-VI compound included in the second shell SH2 may be selected from the group consisting of binary compounds selected from the group consisting of MgO, MgS, MgSe, MgTe, ZnO, ZnS, ZnSe, ZnTe, and a (e.g., any suitable) mixture thereof. For example, the second shell SH2 may include at least one of MgO, MgS, MgSe, MgTe, ZnO, ZnS, ZnSe, or ZnTe. In one or more embodiments, the second shell SH2 may include zinc (Zn) and sulfur(S). The second shell SH2 may include ZnS, but the present disclosure is not limited thereto.

In the Group II-VI compound, each element included in the multi-element compound such as the binary compound may be present in particles at a substantially uniform concentration or a non-uniform (substantially non-uniform) concentration. For example, the formulae above indicate the types (kinds) of elements included in the Group II-VI compound, and an element ratio in the compound may be the same or different.

In one or more embodiments, the second shell SH2 may have a greater band gap than the core CO. For example, the second shell SH2 may have a greater band gap than the core CO which has a band gap of about 1.5 eV to about 3.3 eV. In one or more embodiments, the second shell SH2 may have a greater band gap than the first shell SH1. For example, the band gap of the second shell SH2 may be greater than a band gap of the core CO and may be about 3.54 eV or less. The quantum dot QD of one or more embodiments includes the second shell SH2 having a band gap adjusted to the range described above, and accordingly, quantum efficiency and stability may be improved. The band gap of the second shell SH2 may be regulated by adjusting the type or kind of element of the third semiconductor nanocrystal included in the second shell SH2, the element ratio of the third semiconductor nanocrystal, and/or the thickness of the second shell SH2, but the present disclosure is not limited to thereto.

The band gap of the second shell SH2 may be greater than the band gaps of the core CO and the first shell SH1 and may be about 3.54 eV or less. For example, if (e.g., when) the second shell SH2 includes ZnS, the band gap of the second shell SH2 may be about 3.54 eV, but the present disclosure is not limited thereto. The quantum dot QD of one or more embodiments has improved quantum efficiency and stability as the second shell SH2 having a greater band gap than the core CO and the first shell SH1 is around (e.g., surrounds) the core CO and the first shell SH1.

In one or more embodiments, the second shell SH2 may have a crystal structure substantially similar to the crystal structure of the core CO and the first shell SH1. For example, the second shell SH2 may include ZnS, and the crystal structure of the second shell SH2 may be a cubic structure.

In one or more embodiments, the second shell SH2 may have a level of lattice constant substantially similar to that of the first shell SH1. For example, the lattice constant of the second shell SH2 may have a difference of about 0.2 Å or less from the lattice constant of the first shell SH1 with respect to the absolute value. The lattice constant of the second shell SH2 may satisfy Equation 2. The second shell SH2 satisfying Equation 2 may have a level of lattice constant substantially similar to that of the first shell SH1.

$$SH 2 ( Å ) = SH 1 ( Å ) \pm 0.2 Å \qquad Equation 2$$

In Equation 2, SH2 is a lattice constant of the second shell SH2, and SH1 is a lattice constant of the first shell SH1.

For example, the second shell SH2 including ZnS may have a lattice constant of about 5.41 Å. The second shell SH2 has a crystal structure and lattice constant substantially similar to the crystal structure and the lattice constant of the first shell SH1, respectively, and may thus be formed to have a sufficient thickness to be around (e.g., surround) the core CO and the first shell SH1 while maintaining a narrow full width of half maximum of the core CO.

The quantum dot QD of one or more embodiments may have a full width of half maximum (FWHM) of an emission wavelength spectrum of about 60 nm or less. For example, the quantum dot QD may have a full width of half maximum (FWHM) of an emission wavelength spectrum of about 25 nm to about 65 nm.

In the quantum dot QD of one or more embodiments, the first shell SH1 includes a structure in which the first shell SH1 is introduced between the core CO and the second shell SH2 so that the first shell SH1 is around (e.g, surrounds) the core CO and the second shell SH2 is around (e.g, surrounds) the first shell SH1, and may thus minimize or reduce an increase in the full width of half maximum of the core CO. In one or more embodiments, in the quantum dot QD of one or more embodiments, the core CO is surrounded by (e.g., covered or encapsulated by) the first shell SH1 and the second shell SH2, and accordingly, the quantum dot QD may have greatly increased light and chemical stability. Light emitted through the quantum dot QD is emitted in all directions, and thus a wide viewing angle may be improved.

In one or more embodiments, the form of the quantum dot QD is not particularly limited as long as it is a form generally used in the art, but, for example, quantum dots in the form of spherical, pyramidal, multi-arm, or cubic nanoparticles, nanotubes, nanowires, nanofibers, nanoplatelets, and/or the like may be used. In one or more embodiments, the quantum dot QD may be spherical.

In one or more embodiments, the quantum dot QD may further include a ligand chemically bonded to a surface. The ligand may be chemically bonded to the surface of the quantum dot QD to passivate the quantum dot QD. For example, the quantum dot QD may further include a ligand chemically bonded to the second shell SH2. In one or more embodiments, the ligand may include an organic ligand or a metal halide.

The quantum dot QD may be synthesized through a wet chemical process, a metal organic chemical vapor deposition process, a molecular beam epitaxy process, or a process substantially similar thereto. The wet chemical process is a method of mixing an organic solvent and a precursor material and then growing a particle crystal of the quantum dot QD. When the crystal grows, the organic solvent naturally serves as a dispersant coordinated to a surface of the crystal of the quantum dot QD and may control the growth of the crystal. Therefore, the wet chemical process is easier than vapor deposition methods such as metal organic chemical vapor deposition (MOCVD) or molecular beam epitaxy (MBE), and may control the growth of particles of the quantum dot QD through a low-cost process.

Hereinafter, a method for manufacturing a quantum dot according to one or more embodiments will be described. However, this is presented as an example, and the method for manufacturing a quantum dot according to the present disclosure is not limited to thereto. The description of the quantum dot QD described above may also apply to the method for manufacturing a quantum dot of one or more embodiments, which will be described in more detail later.

For example, the method for manufacturing a quantum dot according to one or more embodiments may include synthesizing a core CO, synthesizing a first shell SH1, and synthesizing a second shell SH2.

The synthesizing of the core CO may include providing a first mixture including a first precursor containing copper atoms, a second precursor containing indium atoms, and a third precursor containing gallium atoms. Thereafter, adding a first solvent and a second solvent to the first mixture to form a second mixture may be included. The first solvent may be trioctyl phosphine oxide, and the second solvent may be trioctylamine, but the present disclosure is not limited thereto. The first solvent and the second solvent may dissolve the first precursor, the second precursor, and the third precursor, and contribute to controlling the concentration and reaction rate of materials in the second mixture.

The second mixture may include the first precursor containing copper atoms, the second precursor containing indium atoms, and the third precursor containing gallium atoms in a certain ratio. In the second mixture, the moles of the second precursor and the third precursor relative to the moles of the first precursor may be included in a ratio (e.g., amount) of about 1 to about 10, but the present disclosure is not limited thereto.

In one or more embodiments, the synthesizing of the core CO may include adding a fourth precursor containing sulfur atoms to the second mixture and then subjecting the mixture to a reaction at a high temperature of 230° C. In the forming of the core CO, the high temperature reaction at 230° C. or higher may continue for about 2 hours, and then the core CO may be formed through cooling and purification processes.

The synthesizing of the first shell SH1 may include mixing a first element precursor and a second element precursor with trioctylamine and vacuum treating the mixture at 120° C. to form a third mixture. Thereafter, in the synthesizing of the first shell SH1, the core CO and a third element precursor utilized in the synthesizing of the core CO may be injected into the third mixture and subjected to a reaction at a high temperature of 250° C. or higher. Maintaining this high temperature reaction at 250° C. or higher for about 40 minutes to form the first shell SH1 around (e.g., surrounding) the core CO may be included.

In the synthesizing of the first shell SH1, the first element precursor may include a Group II element. For example, the first element precursor may include zinc atoms or magnesium atoms. The second element precursor may include a Group III element. For example, the second element precursor may include at least one of aluminum atoms, gallium atoms, or indium atoms. The third element precursor may include a Group VI element. For example, the third element precursor may include at least one of sulfur atoms or selenium atoms. In one or more embodiments, the first element precursor may include zinc atoms, the second element precursor may include gallium atoms, and the third element precursor may include sulfur atoms, but the present disclosure is not limited thereto.

The synthesizing of the second shell SH2 may further include adding a fourth element precursor and a fifth element precursor to a first particle including the core CO and the first shell SH1 after the forming of the first shell SH1 to form the second shell around (e.g., surrounding) the first shell.

In the forming of the second shell SH2, the fourth element precursor may include a Group II element. For example, the fourth element precursor may include at least one of zinc atoms or magnesium atoms. The fifth element precursor may include a Group VI element. For example, the fifth element precursor may include at least one of selenium atoms, sulfur atoms, tellurium atoms, or oxygen atoms. In one or more embodiments, the fourth element precursor may include zinc atoms and the fifth element precursor may include sulfur atoms.

In the forming of the second shell SH2, the fourth element precursor and the fifth precursor may be injected into the first particles, the temperature may be raised to 280° C., and then the reaction may be maintained for 30 minutes. Thereafter, the quantum dots QD of one or more embodiments including the first shell SH1 around (e.g., surrounding) the core CO and the second shell SH2 around (e.g., surrounding) the first shell SH1 may be manufactured through cooling and purification processes.

Table 1 shows a crystal structure, a lattice constant, and a band gap for a quantum dot of Example 1. In Table 1, Example 1 includes a core containing copper, indium, gallium, and sulfur, a first shell around (e.g., surrounding) the core and containing zinc, gallium, and sulfur, and a second shell around (e.g., surrounding) the first shell and containing ZnS. That is, the quantum dot of Example 1 has a structure of CuInGaS—ZnGaS—ZnS (core-first shell-second shell).

TABLE 1

| | | Crystal | Lattice | Band |
|---|---|---|---|---|
| | Composition | structure | constant (Å) | gap (eV) |
| Core | CuInGaS | Tetragonal | 5.35 | 2.0 |
| First shell | ZnGaS | Tetragonal | 5.28 | 3.18 |
| Second shell | ZnS | Cubic | 5.41 | 3.54 |

Referring to Table 1, it is determined that in the quantum dot of Example 1, the band gap of the first shell has a value between the band gap of the core and the band gap of the second shell. In addition, it is determined that in the quantum dot of Example 1, the first shell has the same crystal structure as the core and has a lattice constant substantially similar to that of the core.

Table 2 shows the evaluation of luminescence properties and quantum yield (QY) of the quantum dots of the Example 1 and a Comparative Example 1. Table 2 shows results of measuring full width of half maximum (FWHM) and quantum yield for the quantum dots of Example 1 and Comparative Example 1. In Table 2, the quantum yield is obtained from results of measuring the quantum dots of Example 1 and Comparative Example 1 in a solution state using QE-2100 equipment.

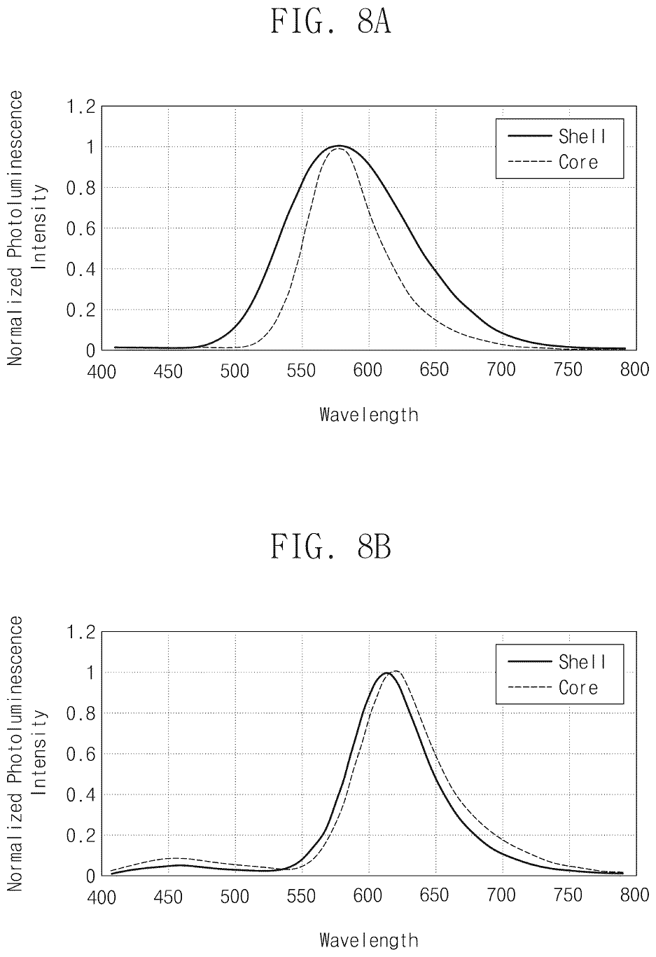

FIGS. 8A and 8B are each a view showing the results of evaluating the luminescence characteristics of the Comparative Example 1 and the Example 1. FIG. 8A is a view showing a photoluminescence (PL) spectrum of a quantum dot of Comparative Example 1. FIG. 8B is a view showing a photoluminescence (PL) spectrum of a quantum dot of Example 1. In FIGS. 8A and 8B, the “core” shown in dotted line shows the photoluminescence spectrum results of only the core, and the “shell” shown in solid line shows the photoluminescence spectrum results of a quantum dot having a shell wrapped around the outside of the core. In addition, in Table 2, the full width of half maximum of the core shows the results of measuring the full width of half maximum of the core alone, and the full width of half maximum of the shell shows the results of measuring the full width of half maximum of the quantum dot having the shell wrapped around the outside of the core.

In Table 2 and FIG. 8A, Comparative Example 1 includes a core containing copper, indium, gallium, and sulfur, and a second shell around (e.g., surrounding) the core and including ZnS. That is, the quantum dot of Comparative Example 1 has a structure of CuInGaS—ZnS (core-second shell) and accordingly does not include a first shell, compared to the quantum dot of Example 1. In Table 2 and FIG. 8B, the quantum dot of Example 1 corresponds to the same quantum dot as Example 1 in Table 1 and has a structure of CuInGaS—ZnGaS—ZnS (core-first shell-second shell).

TABLE 2

| | Full width of half | Full width of half | Quantum |
|---|---|---|---|
| | maximum | maximum | efficiency |
| | (nm) of core | (nm) of shell | (%) |
| Example 1 | 62 | 65 | 85 |
| Comparative | 60 | 105 | 85 |
| Example 1 | | | |

Referring to Table 2 and FIGS. 8A and 8B, it is seen that the quantum dots of Example 1 and Comparative Example 1 each have a core of emission wavelength of about 550 nm to about 680 nm and a full width of half maximum of 65 nm or less. In addition, it is seen that Example 1, which includes the core, the first shell, and the second shell according to one or more embodiments all together, exhibits a high quantum yield of 85%. It was determined that Comparative Example 1 also exhibited a quantum yield at the same level as Example 1. Accordingly, it is seen that the quantum dot of Example 1 shows excellent or suitable quantum yield even if (e.g., when) including multiple shells compared to Comparative Example 1.

Further, the quantum dot of Example 1 had a first shell of ZnGaS introduced between the core and the second shell, and was shown to have a full width of half maximum of 65 nm, which was an increased full width of half maximum by 3 nm compared to the full width of half maximum of 62 nm for the core. That is, it is seen that the increase in full width of half maximum of the quantum dot of Example 1 was minimized or reduced even when multiple shells were introduced on an outer surface of the core. Accordingly, color reproducibility may be improved using the quantum dot of Example 1. In the quantum dot of Example 1, it was determined that gallium components contained in the core were also included in the first shell, and the gallium components of the first shell were distributed on the outside of the core, that is, around an interface between the core and the first shell to prevent or reduce zinc components of the first shell and the second shell from spreading into the core, resulting in small changes in an amount of the full width of half maximum.

However, it is seen that the quantum dot of Comparative Example 1 had a structure in which the first shell is not introduced between the core and the second shell and the second shell directly surrounded the core, and thus had an increased full width of half maximum by 45 nm compared to the core. Accordingly, it is seen that the quantum dot of Comparative Example 1, in which the first shell of ZnGaS was not introduced between the core and the second shell, had a greatly increased full width of half maximum compared to the core, resulting in degraded color reproducibility. In the quantum dot of Comparative Example 1, it was determined that the zinc components of the second shell spread into the core, resulting in a large change in the full width of half maximum.

In addition, referring to FIGS. 8A and 8B, it is seen that the quantum dot of Example 1 showed little change in emission wavelength even when a shell was formed on the core, whereas the quantum dot of Comparative Example 1 showed a large change in emission wavelength when a shell was formed on the core. Accordingly, it was determined that the quantum dot of Example 1 sufficiently obtained shell stability and thus maintained the core characteristics well compared to the quantum dot of Comparative Example 1.

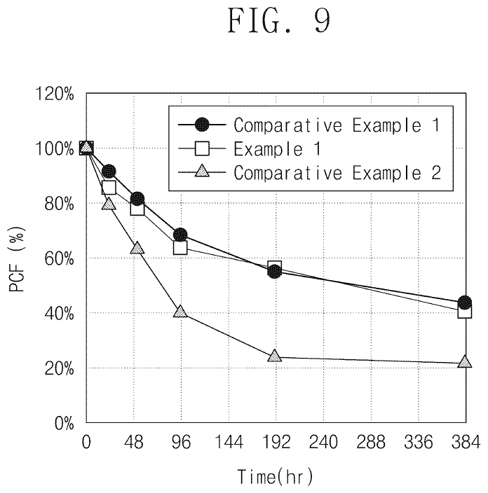

Table 3 and FIG. 9 each show the results of evaluating light stability of the Example 1 and Comparative Example 1 and Comparative Example 2. In Table 3 and FIG. 9, the light stability evaluation is the result of measuring power conversion efficiency (PCE) over time. In Table 2 and FIG. 9, the quantum dots of Example 1, Comparative Example 1, and Comparative Example 2 are shown by adding a quantum dot in an amount of 8 wt % to a sample and exposing the mixture to blue light at 100,000 nits, and then measuring light retention over time. In Table 3 and FIG. 9, Example 1 and Comparative Example 1 correspond to the quantum dots of Example 1 and Comparative Example 1 in Table 2 above. Comparative Example 2 includes a core containing silver, indium, gallium, and sulfur, and a shell around (e.g., surrounding) the core and including GaS. That is, the quantum dot of Comparative Example 2 has a structure of AgInGaS—GaS and includes one shell compared to the quantum dot of Example 1.

TABLE 3

| | 0 | 24 (hr) | 53 (hr) | 96(hr) | 192 (hr) | 384 (hr) |
|---|---|---|---|---|---|---|
| Example 1 | 100% | 85% | 78% | 63% | 56% | 40% |
| Comparative | 100% | 90% | 81% | 67% | 55% | 43% |
| Example 1 | | | | | | |
| Comparative | 100% | 78% | 63% | 39% | 23% | 21% |
| Example 2 | | | | | | |

Referring to Table 3 and FIG. 9 together, Comparative Example 1 and Example 1 showed substantially similar values in the light stability evaluation. That is, over time, the quantum dot of Example 1 may be seen to exhibit quantum yield substantially similar to that of Comparative Example 1. For example, it is considered that even when the first shell is introduced between the core and the second shell to include multiple shells, the luminescence characteristics of the quantum dot are maintained at a substantially similar level to that of typical quantum dots in which the first shell is not introduced.

In addition, Comparative Example 2 showed significantly reduced light stability results compared to Example 1, indicating that the quantum dot without the first shell and the second shell according to one or more embodiments had insufficient luminescence properties.

Considering Tables 1 to 3 and FIGS. 8A to 9, it is seen that according to the introduction of the first shell, the light stability of the quantum dot of Example is shown to be at a substantially similar level to that of Comparative Example or to be significantly improved, and an increase in full width of half maximum may be minimized or reduced. For example, as for one or more embodiments including the first shell having a band gap between the core and the second shell and having the same crystal structure as the core and a substantially similar lattice constant to that of the core, as the first shell is introduced between the core and the second shell, the light emission wavelength characteristics and luminous efficiency of a light emitting element according to one or more embodiments may be expected to be maintained at a satisfactory level or to be improved. In addition, a display device including the quantum dot according to one or more embodiments may also be expected to exhibit excellent or suitable display quality in terms of luminescence characteristics and display efficiency.

A quantum dot of one or more embodiments includes different semiconductor nanocrystals and includes a core and multiple shells having specific band gap characteristics, and may thus maintain a full width of half maximum of the core, thereby exhibiting improved color reproducibility and stability, and satisfactory quantum efficiency.

A light emitting element of one or more embodiments includes the quantum dot described above in an emission layer, and may thus exhibit satisfactory light emission characteristics and excellent or suitable element quality.

A display device of one or more embodiments includes a light emitting element containing the quantum dot described above in an emission layer, and may thus exhibit excellent or suitable display quality.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A quantum dot comprising:
a core comprising a first semiconductor nanocrystal;
a first shell around the core and comprising a second semiconductor nanocrystal different from the first semiconductor nanocrystal; and
a second shell around the first shell and comprising a third semiconductor nanocrystal different from the first semiconductor nanocrystal and the second semiconductor nanocrystal,
wherein the first semiconductor nanocrystal comprises a Group I-III-VI compound,
the second semiconductor nanocrystal comprises at least one of a Group I-III-VI compound or a Group II-III-VI compound,
the third semiconductor nanocrystal comprises a Group II-VI compound, the core has a band gap of about 1.5 eV to about 3.3 eV,
a band gap of the second shell is greater than the band gap of the core and is about 3.54 eV or less, and
a band gap of the first shell is greater than the band gap of the core and smaller than the band gap of the second shell.

2. The quantum dot of claim 1, wherein the core comprises copper, indium, gallium, and sulfur.

3. The quantum dot of claim 1, wherein the first shell has the same crystal structure as the core.

4. The quantum dot of claim 3, wherein the first shell satisfies Equation 1:
$$SH 1 ( Å ) = CO ( Å ) \pm 0.2 Å \qquad Equation 1$$
wherein in Equation 1, SH1 is a lattice constant of the first shell and CO is a lattice constant of the core.

5. The quantum dot of claim 1, wherein the second semiconductor nanocrystal comprises the Group I-III-VI compound and the Group II-III-VI compound,
wherein the Group I-III-VI compound of the first shell is selected from the group consisting of:
a ternary compound selected from the group consisting of a compound containing Ag—In—S, a compound containing Ag—Ga—S, a compound containing Ag—Al—S, a compound containing Ag—In—Se, a compound containing Ag—Ga—Se, a compound containing Ag—Al—Se, a compound containing Cu—In—S, a compound containing Cu—Ga—S, a compound containing Cu—Al—S, a compound containing Cu—In—Se, a compound containing Cu—Ga—Se, a compound containing Cu—Al—Se, and a mixture thereof; and
a quaternary compound selected from the group consisting of a compound containing Ag—In—Ga—S, a compound containing Ag—Ga—Se—S, and a mixture thereof, and
wherein the Group II-III-VI compound of the first shell is selected from the group consisting of:
a ternary compound selected from the group consisting of a compound containing Zn—In—S, a compound containing Zn—Ga—S, a compound containing Zn—Al—S, a compound containing Zn—In—Se, a compound containing Zn—Ga—Se, a compound containing Zn—Al—Se, a compound containing Mg—In—S, a compound containing Mg—Ga—S, a compound containing Mg—Al—S, a compound containing Mg—In—Se, a compound containing Mg—Ga—Se, a compound containing Mg—Al—Se, and a mixture thereof; and
a quaternary compound selected from the group consisting of a compound containing Zn—In—Ga—S, a compound containing Zn—In—Se—S, and a mixture thereof.

6. The quantum dot of claim 1, wherein the first shell comprises the Group II-III-VI compound, and
in the Group II-III-VI compound, a gallium atom is in as a Group III element.

7. The quantum dot of claim 1, wherein the first shell comprises zinc, gallium, and sulfur.

8. The quantum dot of claim 1, wherein the second shell comprises at least one of MgO, MgS, MgSe, MgTe, ZnO, ZnS, ZnSe, or ZnTe.

9. The quantum dot of claim 8, wherein the second shell comprises ZnS.

10. The quantum dot of claim 1, wherein the quantum dot has a diameter of about 2 nm to about 10 nm.

11. The quantum dot of claim 1, wherein the quantum dot has a full width of half maximum of about 65 nm or less.

12. The quantum dot of claim 1, wherein the quantum dot has a central emission wavelength of about 380 nm to about 800 nm.

13. A light emitting element comprising:
a first electrode;
a second electrode opposite the first electrode;
an emission layer between the first electrode and the second electrode and comprising a quantum dot; and
a functional layer between the emission layer and the first electrode and/or between the emission layer and the second electrode,
wherein the quantum dot comprises:
a core comprising a first semiconductor nanocrystal;
a first shell around the core and comprising a second semiconductor nanocrystal different from the first semiconductor nanocrystal; and
a second shell around the first shell and comprising a third semiconductor nanocrystal different from the first semiconductor nanocrystal and the second semiconductor nanocrystal, and
wherein the first semiconductor nanocrystal comprises a Group I-III-VI compound,
the second semiconductor nanocrystal comprises at least one of a Group I-III-VI compound or a Group II-III-VI compound,
the third semiconductor nanocrystal comprises a Group II-VI compound,
the core has a band gap of about 1.5 eV to about 3.3 eV,
a band gap of the second shell is greater than the band gap of the core and is about 3.54 eV or less, and
a band gap of the first shell is greater than the band gap of the core and smaller than the band gap of the second shell.

14. The light emitting element of claim 13, wherein the core comprises copper, indium, gallium, and sulfur.

15. The light emitting element of claim 13, wherein the second semiconductor nanocrystal comprises the Group I-III-VI compound and the Group II-III-VI compound,
wherein the Group I-III-VI compound of the first shell is selected from among a ternary compound selected from the group consisting of:
a compound containing Ag—In—S, a compound containing Ag—Ga—S, a compound containing Ag—Al—S, a compound containing Ag—In—Se, a compound containing Ag—Ga—Se, a compound containing Ag—Al—Se, a compound containing Cu—In—S, a compound containing Cu—Ga—S, a compound containing Cu—Al—S, a compound containing Cu—In—Se, a compound containing Cu—Ga—Se, a compound containing Cu—Al—Se, and a mixture thereof; and
a quaternary compound selected from the group consisting of a compound containing Ag—In—Ga—S, a compound containing Ag—Ga—Se—S, and a mixture thereof, and
wherein the Group II-III-VI compound of the first shell is selected from the group consisting of:
a ternary compound selected from the group consisting of a compound containing Zn—In—S, a compound containing Zn—Ga—S, a compound containing Zn—Al—S, a compound containing Zn—In—Se, a compound containing Zn—Ga—Se, a compound containing Zn—Al—Se, a compound containing Mg—In—S, a compound containing Mg—Ga—S, a compound containing Mg—Al—S, a compound containing Mg—In—Se, a compound containing Mg—Ga—Se, a compound containing Mg—Al—Se, and a mixture thereof; and
a quaternary compound selected from the group consisting of a compound containing Zn—In—Ga—S, a compound containing Zn—In—Se—S, and a mixture thereof.

16. The light emitting element of claim 13, wherein the first shell comprises zinc, gallium, and sulfur.

17. The light emitting element of claim 13, wherein the second shell comprises at least one of MgO, MgS, MgSe, MgTe, ZnO, ZnS, ZnSe, or ZnTe.

18. The light emitting element of claim 13, wherein the functional layer comprises a hole transport region below the emission layer, and an electron transport region above the emission layer.

19. A display device comprising:
a circuit layer; and
a display element layer on the circuit layer and comprising a light emitting element and a pixel defining film in which a pixel opening is defined;
wherein the light emitting element comprises:
a first electrode;
a second electrode facing the first electrode;
an emission layer between the first electrode and the second electrode and comprising a quantum dot; and
a functional layer between the emission layer and the first electrode and/or between the emission layer and the second electrode,
the quantum dot comprises:
a core comprising a first semiconductor nanocrystal;
a first shell around the core and comprising a second semiconductor nanocrystal different from the first semiconductor nanocrystal; and
a second shell around the first shell and comprising a third semiconductor nanocrystal different from the first semiconductor nanocrystal and the second semiconductor nanocrystal,
the first semiconductor nanocrystal comprises a Group I-III-VI compound,
the second semiconductor nanocrystal comprises at least one of a Group I-III-VI compound or a Group II-III-VI compound,
the third semiconductor nanocrystal comprises a Group II-VI compound,
the core has a band gap of about 1.5 eV to about 3.3 eV,
a band gap of the second shell is greater than the band gap of the core, and is about 3.54 eV or less, and
a band gap of the first shell is greater than the band gap of the core and smaller than the band gap of the second shell.

20. The display device of claim 19, wherein the core comprises copper, indium, gallium, and sulfur.

21. The display device of claim 19, wherein the first shell comprises zinc, gallium, and sulfur.

22. The display device of claim 19, wherein the second shell comprises ZnS.

23. The display device of claim 19, wherein the functional layer comprises:
a first functional layer between the first electrode and the emission layer; and
a second functional layer between the emission layer and the second electrode, and
one of the first functional layer or the second functional layer is a hole transport region, and the other of the first functional layer or the second functional layer is an electron transport region.

24. The display device of claim 19, wherein the emission layer is in the pixel opening, and
the functional layer is a common layer overlapping the emission layer and the pixel defining film.

25. The display device of claim 19, wherein the light emitting element comprises a first light emitting element comprising a first emission layer that to emit blue light, a second light emitting element comprising a second emission layer that is to emit green light, and a third light emitting element comprising a third emission layer that is to emit red light, and
at least one of the first emission layer, the second emission layer, or the third emission layer comprises the quantum dot.
